(19) United States
(12) Patent Application Publication
(10) Pub. No.: US 2007/0252154 A1
(43) Pub. Date: Nov. 1, 2007

(54) Semiconductor Chip Manufacturing Method, Semiconductor Chip, Semiconductor Thin Film Chip, Electron Tube and Photo-Detecting Device

(76) Inventors: Shoichi Uchiyama, Shizuoka (JP); Ryuji Sugiura, Shizuoka (JP); Ryo Kawashima, Shizuoka (JP)

Correspondence Address: DRINKER BIDDLE & REATH (DC), 1500 K STREET, N.W., SUITE 1100, WASHINGTON, DC, 20005-1209, US

(21) Appl. No.: 10/571,594

(22) PCT Filed: Sep. 9, 2004
(86) PCT No.: PCT/JP04/13166

§ 371 Date: Mar. 20, 2007

(30) Foreign Application Priority Data
Sep. 11, 2003 (JP) 2003-320121

(51) Int. Cl. H01L 31/0256; H01L 21/461; H01L 29/12

(52) U.S. Cl. 257/77; 257/433; 438/105; 257/E31.003; 257/E29.068; 257/E21.049

(57) ABSTRACT

The present invention relates to a semiconductor chip manufacturing method in which a semiconductor thin film can be cut in a relatively short time and the cut surface can be relatively smoothly formed. When an Si substrate having a diamond thin film formed on the surface thereof is cut in the chip form, a modified region based on multiphoton absorption is formed as a cutting starting point region formed along a cutting planned line by irradiating at least the Si substrate with a laser beam whose condense point is focused to the inside of the Si substrate, along the cutting planned line. The diamond thin film is cut in connection with the cutting of the Si substrate along the cutting starting point region defined by the modified region.

### TECHNICAL FIELD

The present invention relates to a semiconductor chip manufacturing method, a semiconductor chip, a semiconductor thin film chip, an electron tube and a photo-detecting device.

### BACKGROUND ART

Various types of semiconductor thin films grown on substrates such as a diamond thin film for photoelectrical conversion, etc., have been recently used for various applications. When such a semiconductor thin film is manufactured, the semiconductor thin film is grown on a wafer by using the CVD method or the like, and then the wafer is cut (diced) to obtain a semiconductor thin film chip having a desired size.

For example, a chipping method of a diamond wafer disclosed in Patent Document 1 is known as a method of cutting a wafer on which a semiconductor thin film is formed. In the Patent Document 1, when a diamond wafer having a diamond thin film formed on the surface of a substrate is cut in the shape of chips, a first groove is formed in the diamond thin film by laser processing, and a second groove is formed on the back surface of the substrate in conformity with the first groove by using a diamond plate. Then, by applying a stress to the diamond wafer, the diamond wafer is cut along the first groove and the second groove.

Furthermore, a laser processing method disclosed in the Patent Document 2 is known as a method of cutting a processing target object such as a substrate or the like with a laser beam. Patent Document 1: Japanese Published Unexamined Patent Application No. 2002-93751 Patent Document 2: Japanese Published Unexamined Patent Application No. 2002-192370

### DISCLOSURE OF THE INVENTION

Problem to be Solved by the Invention

The inventors have made detailed studies on the prior art, and have consequently found the following problem. That is, with respect to the method disclosed in the Patent Document 1, the step of forming the second groove by using the diamond plate requires much time to cut the substrate. In addition, a large amount of powder dust is generated in this step, and thus a cleaning step of washing and removing the powder dust is separately required, so that the manufacturing time is further lengthened. Furthermore, the second groove is formed by cutting the substrate with the diamond blade, and thus the bottom surface of the second groove becomes rough. Accordingly, chipping or the like is liable to occur on the cut surface with the second groove as a starting point, and the cut surface is not smooth.

The present invention has been implemented in order to solve the above problem, and has an object to provide a semiconductor chip manufacturing method in which a semiconductor thin film can be cut in a relatively short time, and the cut surface can be formed relatively smoothly, a semiconductor chip, a semiconductor thin film chip, and an electron tube and a photo-detecting device each comprising the semiconductor thin film chip.

Means for Solving Problem

In order to solve the above problem, a semiconductor chip manufacturing method according to the present invention comprises the steps of: forming a cutting starting point region along a cutting planned line in a semiconductor member which comprises a substrate and a semiconductor thin film provided on the surface of the substrate, wherein, as a cutting starting point region, a modified region based on multiphoton absorption is formed in the substrate by irradiating the substrate with a laser beam whose condense point is focused to the inside of the substrate, along the cutting planned line; and cutting the semiconductor thin film by cutting the substrate along the cutting starting point region.

The semiconductor chip manufacturing method according to the present invention comprises the steps of: forming a cutting starting point, region along a cutting planned line in a semiconductor member which comprises a substrate and a semiconductor thin film provided on the surface of the substrate, wherein, as a cutting starting point region, a molten processed region is formed in the substrate by irradiating the substrate with a laser beam whose condense point is focused to the inside of the substrate, along the cutting planned line; and cutting the semiconductor thin film by cutting the substrate along the cutting starting point region.

Also, the semiconductor chip manufacturing method according to the present invention comprises the steps of: forming a cutting starting point region along a cutting planned line in a semiconductor member which comprises a substrate and a semiconductor thin film provided on the surface of the substrate, wherein, as cutting starting point regions, modified regions based on multiphoton absorption are formed in the substrate and the semiconductor thin film by irradiating the substrate with a laser beam whose condense point is focused to the inside of the substrate, along the cutting planned line, and by irradiating the semiconductor thin film with a laser beam whose condense point is focused to the inside of the semiconductor thin film, along the cutting planned line; and cutting the semiconductor thin film by cutting the semiconductor thin film and the substrate along the cutting starting point regions.

Furthermore, the semiconductor chip manufacturing method according to the present invention comprises the steps of: forming a cutting starting point region along a cutting planned line in a semiconductor member which comprises a substrate and a semiconductor thin film provided on the surface of the substrate, wherein, as cutting starting point regions, molten processed regions are formed in the substrate and the semiconductor thin film by irradiating the substrate with a laser beam whose condense point is focused to the inside of the substrate, along the cutting planned line, and by irradiating the semiconductor thin film with a laser beam whose condense point is focused to the inside of the semiconductor thin film, along the cutting planned line; and cutting the semiconductor thin film by cutting the semiconductor thin film and the substrate along the cutting starting point regions.

In accordance with to the semiconductor chip manufacturing method described above, the substrate and the semiconductor thin film are cut by irradiating the laser beam, and thus the substrate and the semiconductor thin film can be cut in a shorter time as compared with a method of forming a groove by using a diamond blade. Furthermore, the substrate and the semiconductor thin film can be broken and cut along the cutting starting point region by relatively small force, and generation of powder dust can be suppressed to a remarkably small level, so that no washing step is required. Furthermore, since the substrate and the semiconductor thin film can be broken and cut along the cutting starting point region by relatively small force, the cut surface can be more smoothly formed as compared with the blade dicing method.

Here, the inside of the substrate (or the inside of the semiconductor thin film) also includes the meaning of “on the surface of the substrate (or on the surface of the semiconductor thin film).” Furthermore, the condense point means as a place at which the laser beam is focused. The cutting starting point region may be defined by a modified region or molten processed region which is continuously formed, or by a modified region or molten processed region which is intermittently formed.

Furthermore, in the semiconductor chip manufacturing chip, in the forming of the cutting starting point region, the cutting starting point region may be formed at the inside of the semiconductor thin film after the cutting starting point region is formed at the inside of the substrate, whereby the cut surface can be formed more smoothly.

In the semiconductor chip manufacturing method, the semiconductor thin film is preferably comprised of one of diamond and materials containing diamond as a main component.

The semiconductor chip manufacturing method may further comprises the step of polishing the surface of the substrate and growing the semiconductor thin film on the surface, prior to the forming of the cutting starting point regions. In this case, it is preferable that a laser beam is irradiated from the substrate surface side in the forming of the cutting starting point region. Accordingly, scattering of the laser beam on the surface of the substrate can be effectively suppressed, and thus the modified region (or the molten processed region) can be suitably formed at the inside of the substrate.

The semiconductor thin film chip according to the present invention is cut together with the substrate, along the cutting starting point region defined by the modified region based on the multiphoton absorption which is a part of the semiconductor thin film formed on the surface of the substrate and formed by irradiating the substrate with a laser beam whose condense point is focused to the inside of the substrate.

Also, the semiconductor thin film chip according to the present invention is cut together with the substrate, along the cutting starting point region defmed by a molten processed region which is a part of the semiconductor thin film formed on the surface of the substrate and formed by irradiating the substrate with a laser beam whose condense point is focused to the inside of the substrate.

Further, the semiconductor thin film chip according to the present invention is a part of a semiconductor thin film formed on the surface of a substrate and cut together with the substrate, along a cutting starting point region defined by a modified region based on multiphoton absorption which is formed by irradiating the substrate with a laser beam whose condense point is focused to the inside of the substrate, and by irradiating the semiconductor thin film with a laser beam whose condense point is focused to the inside of the semiconductor thin film.

Furthermore, the semiconductor thin film chip according to the present invention is a part of a semiconductor thin film formed on the surface of a substrate and cut together with the substrate, along a cutting starting point region defined by a molten processed region which is formed by irradiating the substrate with a laser beam whose condense point is focused to the inside of the substrate, and by irradiating the semiconductor thin film with a laser beam whose condense point is focused to the inside of the semiconductor thin film.

In accordance with any one of the semiconductor thin film chips as described above, the substrate and the semiconductor thin film are cut by irradiating the laser beam, and thus the substrate and the semiconductor thin film are cut in a shorter time as compared with a method using a diamond blade. Furthermore, since the substrate and the semiconductor thin film are broken and cut along the cutting starting point region by relatively smaller force, generation of powder dust can be suppressed to a remarkably small level and thus no washing step is required. Furthermore, since the substrate and the semiconductor thin film can be broken and cut along the cutting starting point region by relatively small force, the cut surface can be formed more smoothly as compared with a method using blade dicing.

In the semiconductor thin film chip of the present invention, it is preferable that the substrate has a flat and smooth surface. By this, the scattering of the laser beam on the surface of the substrate can be effectively suppressed. Therefore, the laser beam is irradiated from the substrate surface as the cutting starting point region, so that the modified region (or the molten processed region) is suitably formed in the substrate.

It is preferable that the semiconductor thin film chip of the present invention is comprised of one of diamond and materials containing diamond as a main component.

The semiconductor chip of the present invention comprises the semiconductor thin film chip obtained as described above and a part of the substrate having the semiconductor thin film chip formed on the surface thereof. According to the semiconductor chip, the substrate and the semiconductor thin film can be cut in a shorter time, and no washing step is required. Furthermore, the cut surface can be more smoothly formed.

An electron tube according to the present invention comprises a semiconductor thin film chip that is comprised of one of diamond and materials containing diamond as a main component and is manufactured as a photoelectric surface for converting incident light to photoelectrons according to the above-described method, and a container for tightly sealing the semiconductor thin film chip under a vacuum state. With this construction, the electron tube has the semiconductor thin film having the smooth cut surface and the manufacturing time thereof can be shortened.

A photo-detecting device according to the present invention comprises a semiconductor thin film chip that is comprised of one of diamond and materials containing diamond as a main component and is manufactured as a photo-detecting face for detecting incident light according to the above-described method, and at least two electrodes provided on the semiconductor thin film chip while being spaced from each other. With this construction, the photo-detecting device has the semiconductor thin film having the smooth cut surface and the manufacturing time thereof can be shortened.

Effect of the Invention

In accordance with the semiconductor chip manufacturing method according to the present invention, the semiconductor chip and the semiconductor thin film chip of the present invention, the semiconductor thin film can be cut in a relatively short time, and the cross-section can be relatively smoothly formed. Furthermore, according to the electron tube and the photo-detecting device of the present invention, there can be provided the electron tube and the photo-detecting device that comprise the semiconductor thin film chip having the smooth cut surface, and for which the manufacturing time can be shortened.

### BRIEF DESCRIPTION OF THE DRAWINGS

FIG. 1 is a plan view showing a processing target object during laser processing;

FIG. 2 is a cross-sectional view showing the processing target object shown in FIG. 1, which is taken along I-I line;

FIG. 3 is a plan view showing the processing target object after the laser processing;

FIG. 4 is a cross-sectional view showing the processing target object shown in FIG. 3, which is taken along II-II line;

FIG. 5 is a cross-sectional view showing the processing target object shown in FIG. 3, which is taken along III-III line;

FIG. 6 is a plan view showing a cut processing target object;

FIG. 7 is a graph showing the relationship between the intensity of the electric field and the size of crack spot in the laser processing method;

FIG. 8 is a cross-sectional view showing the processing target object in a step of the laser processing method;

FIG. 9 is a cross-sectional view showing the processing target object in a step of the laser processing method;

FIG. 10 is a cross-sectional view showing the processing target object in a step of the laser processing method;

FIG. 11 is a cross-sectional view showing the processing target object in a step of the laser processing method;

FIG. 12 shows a photograph of the cross-section of a part of a silicon wafer cut by the laser processing method;

FIG. 13 is a graph showing the relationship between the wavelength of the laser beam and transmittance inside a silicon substrate in the laser processing method;

FIG. 14 is a schematic diagram of a laser processing device;

FIG. 15 is a flowchart for explaining the laser processing method;

FIG. 16 shows diagrams for explaining a method of manufacturing a semiconductor chip and a semiconductor thin film chip;

FIG. 17 is a diagram for explaining the method of manufacturing the semiconductor chip and the semiconductor thin film chip;

FIG. 18 shows diagrams for explaining the method of manufacturing the semiconductor chip and the semiconductor thin film chip;

FIG. 19 shows diagrams for explaining the method of manufacturing the semiconductor chip and the semiconductor thin film chip;

FIG. 20 shows diagrams for explaining the method of manufacturing the semiconductor chip and the semiconductor thin film chip;

FIG. 21 shows diagrams for explaining the method of manufacturing the semiconductor chip and the semiconductor thin film chip;

FIG. 22 is a perspective view showing the semiconductor chip manufactured by an embodiment of the manufacturing method according to the present invention;

FIG. 23 is a cross-sectional view showing a modification of the semiconductor chip manufacturing method, the semiconductor chip and the semiconductor thin film chip according to the present invention;

FIG. 24 shows photographs of an example (first sample) of the semiconductor chip and the semiconductor thin film chip according to the embodiment;

FIG. 25 shows photographs of another example (second sample) of the semiconductor chip and the semiconductor thin film chip according to the embodiment;

FIG. 26 shows photographs of another example (third sample) of the semiconductor chip and the semiconductor thin film chip according to the embodiment;

FIG. 27 is a diagram showing the cross-sectional structure of a photomultiplier tube which is a first embodiment of an electron tube according to the present invention;

FIG. 28 is a diagram showing the cross-sectional structure of an image tube which is a second embodiment of the electron tube according to the present invention;

FIG. 29 is a diagram showing the cross-sectional structure of a third embodiment of the electron tube according to the present invention;

FIG. 30 is a diagram showing the cross-sectional structure of a fourth embodiment of the electron tube according to the present invention; and

FIG. 31 is a diagram showing the cross-sectional structure of an embodiment of a photo-detecting device according to the present invention.

### DESCRIPTION OF THE REFERENCE NUMERALS

1 . . . processing target object; 5 . . . cut planned line; 7 . . . modified region; 8, 8a to 8g . . . cutting starting point region; 9 . . . crack area; 10 . . . Si substrate; 11 . . . silicon wafer; 12, 22, 42, 52, 62, 72 . . . diamond thin film; 13 . . . molten processed region; 14 . . . cut planned line; 16, 26, 46, 56, 66, 76 . . . chip; 20 . . . photomultiplier tube; 21 . . . valve; 24, 44, 54, 64, 64 . . . substrate; 25 . . . dynode; 40 . . . image tube; 41 . . . ceramic side tube; 45 . . . fluorescent material; 50, 60 . . . electron tube; 51, 61, 71 . . . package; 63, 73 . . . incident window; 70 . . . photo-detecting device; 77a, 77b . . . electrode; 100 . . . laser processing device; 101 . . . laser light source; 105 . . . condenser lens; 109 . . . X-axis stage; 111 . . . Y-axis stage; 113 . . . Z-axis stage; e, e1 . . . photoelectron; e2 . . . secondary electron; L . . . laser beam; L1 . . . light, L2, L3 . . . optical image; P . . . condense point.

### BEST MODES FOR CARRYING OUT THE INVENTION

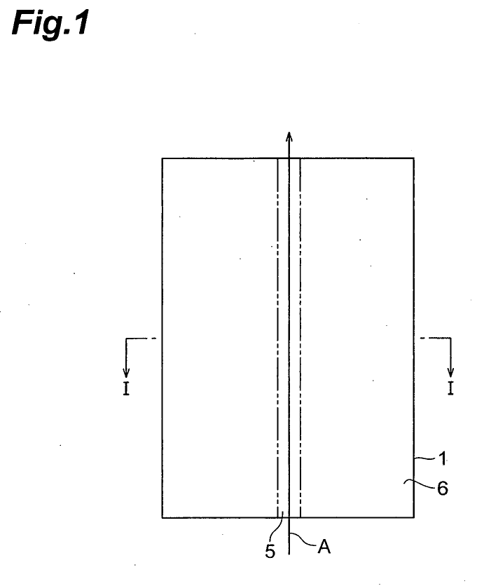

Respective embodiments of a semiconductor chip manufacturing method, a semiconductor chip, a semiconductor thin film chip, an electron tube and a photo-detecting device according to the present invention will be described in detail with reference to FIGS. 1 to 31. In the description of the drawings, the same elements are represented by the same reference numerals, and the overlapping description thereof is omitted.

First, an embodiment of the semiconductor chip manufacturing method, the semiconductor chip and the semiconductor thin film chip according to the present invention will be described. In the semiconductor chip manufacturing method, the semiconductor chip and the semiconductor thin film chip according to the embodiment, a modified region or molten processed region which is based on multiphoton absorption is formed by irradiating a laser beam to the inside of the wafer substrate. Therefore, the laser processing method, particularly, the multiphoton absorption will be first described.

When the energy hv of photon is smaller than the absorption band gap E_{G} of material, the material is optically transparent. Accordingly, the condition that absorption occurs in the material is hν>E_{G}. However, even when the material is optically transparent, by increasing the intensity of the laser beam remarkably, absorption occurs in the material under the condition of nhν>E_{G} (n=2, 3, 4, . . . ). This phenomenon is called multiphoton absorption. In the case of a pulse wave, the laser beam intensity is determined by the peak power density (W/cm²) at the condense point of the laser beam, and multiphoton absorption occurs under the condition that the peak power density is above 1×10⁸ (W/cm²). The peak power density is determined by (energy per pulse of laser beam at condense point)/(beam spot cross-sectional area of laser beam × pulse width). Furthermore, in the case of a continuous wave, the laser beam intensity is determined by the intensity of the electric field (W/cm²) at the condense point of the laser beam.

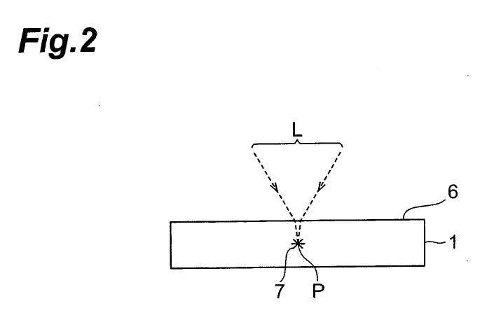

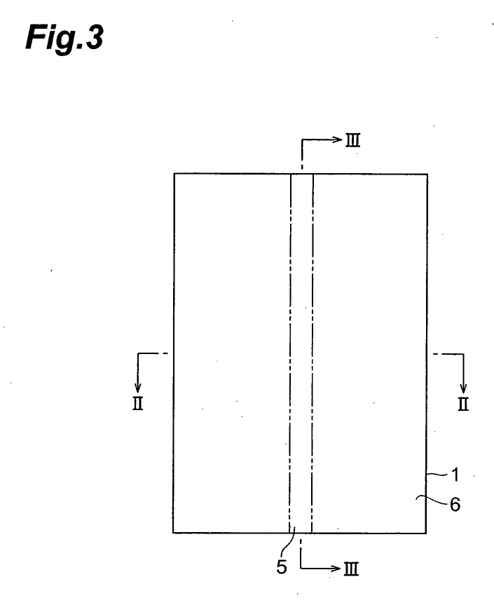

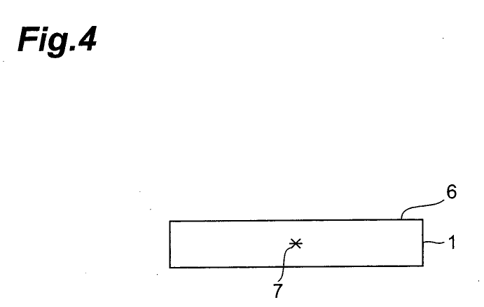

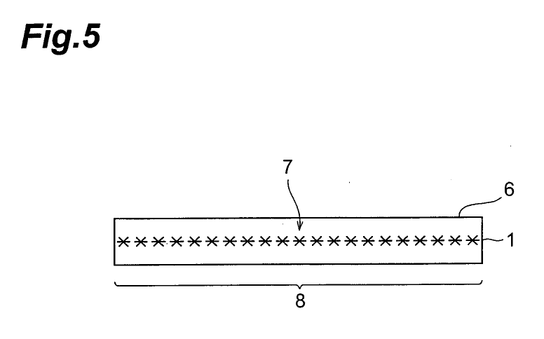

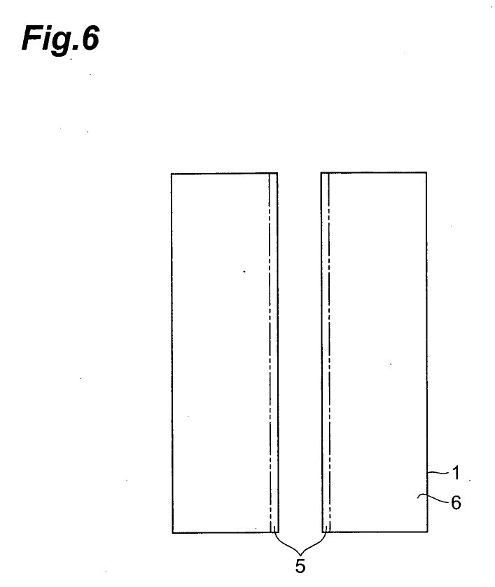

The principle of the laser processing using the multiphoton absorption as described above will be described with reference to FIGS. 1 to 6. FIG. 1 is a plan view showing a processing target object 1 during the laser processing, FIG. 2 is a cross-sectional view showing the processing target object of FIG. 1 which is taken along I-I line, FIG. 3 is a plan view showing the processing target object after the laser processing, FIG. 4 is a cross-sectional view showing the processing target object shown in FIG. 3 which is taken along II-II line, FIG. 5 is a cross-sectional view showing the processing target object shown in FIG. 3 which is taken along III-III line, and FIG. 6 is a plan view showing the cut processing target object 1.

As shown in FIGS. 1 and 2, a desired cutting planned line 5 is set on the processing target object 1 as shown in FIGS. 1 and 2. The cutting planned line 5 is a virtual line extending linearly. A line may be actually drawn on a wafer as the cutting planned line 5. In the embodiment, a laser beam L is irradiated to the processing target object 1 so that the condense point P is focused to the inside of the processing target object 1 under the condition that multiphoton absorption occurs, thereby forming a modified region 7. The condense point P means the place to which the laser beam L is focused.

By relatively moving the laser beam L along the cutting planned line 5 (that is, along the direction of an arrow A), the condense point P is moved along the cutting planned line 5, whereby the modified region as shown in FIGS. 3 to 5 is formed only inside the processing target object 1. The cutting starting point region 8 is an area defined by the modified region 7 thus formed. The laser processing method does not form the modified region 7 by heating the processing target object 1 through the absorption of the laser beam L by the processing target object 1, but forms the modified region 7 by transmitting the laser beam L through the processing target object 1 to induce multiphoton absorption in the processing target object 1. Accordingly, the laser beam L is hardly absorbed on the surface 6 of the processing target object 1, and thus the surface 5 of the processing target object 1 is not melted. It is preferable that the surface 6 of the processing target object 1 is flat and smooth in order to prevent scattering of the laser beam on the surface 6.

When a starting point exists at a place to be cut in the cross-section of the processing target object 1, the processing target object 1 is broken from the starting point. Therefore, the processing target object 1 can be cut by relatively small force as shown in FIG. 6. Accordingly, the processing target object 1 can be cut smoothly, easily, highly precisely and efficiently without generating any unnecessary cracks such as chipping or the like on the surface of the processing target object 1.

The following two cases may be considered to cut the substrate with the cutting starting point region as a starting point. According to one manner, after the cutting starting point region is formed, the substrate is broken and thus cut with the cutting starting point region as a starting point by applying a man-made stress to the substrate. This is a case where the thickness of the substrate is large. The application of the man-made stress means that flexural stress or shear stress is applied to the substrate along the cutting starting point region of the substrate or thermal stress is generated by applying a temperature difference to the substrate. According to the other manner, by forming the cutting starting point region, the substrate is naturally broken toward the cross-sectional direction (thickness direction) of the substrate with the cutting starting point region as a starting point, and as a result the substrate is cut. For example, when the thickness of the substrate is small, this would be possible if the cutting starting point region is formed by a modified region of one row. When the thickness of the substrate is large, this would be possible if the cutting starting point region is formed by modified regions of a plurality of rows formed in the thickness direction. When the substrate is naturally broken, at the place to be cut, breaking does not progress to the surface of the portion corresponding to a site at which no cutting starting point region is formed, and only the portion corresponding to a site at which the cutting starting point region is formed can be broken, so that the breaking and cutting can be excellently controlled. There is a recent tendency that the thickness of the wafer substrate, etc., is reduced, and the breaking and cutting method having excellent controllability as described above is very effective.

The following three areas may be considered as the modified region formed by multiphoton absorption.

(1) When the modified region is a crack area in which one or more cracks are contained

For example, the condense point is focused to the inside of the processing target object formed of diamond, sapphire, glass or the like, and a laser beam is irradiated under the condition that the intensity of the electric field at the condense point is equal to 1×10⁸(W/cm²) or more and has a pulse width of 1 μs or less. The pulse width is set so that multiphoton absorption occurs, the surface of the processing target object suffers no unnecessary damage, and a crack area is formed only inside the processing target object. Accordingly, a so-called optical damage phenomenon caused by multiphoton absorption occurs inside the processing target object. Thermal strain is induced inside the processing target object by the optical damage, whereby a crack area is formed inside the processing target object. The upper limit value of the electric field intensity is set to 1×10¹²(W/cm²), for example. The pulse width is preferably set to 1 ns to 200 ns, for example.

The inventors have experimentally determined the relationship between the electric field intensity and the size of the crack. The experimental condition is as follows.

(A) Processing target object: Pyrex (registered trademark) glass (thickness 700 μm)

(B) Laser

light source: semiconductor laser pumping Nd:YAG laser
wavelength: 1064 nm
cross-sectional area of laser beam spot: 3.14×10⁻⁸ cm²
oscillating mode: Q switch pulse
repetitive frequency: 100 kHz
pulse width: 30 ns
output: output<1 mJ/pulse
laser beam quality: TEM₀₀
polarization characteristic: linear polarization
   (C) Condenser lens
transmittance to laser beam wavelength: 60%
   (D) Moving speed of mount table on which processing target object is mounted: 100 mm/second

The laser beam quality of TEM₀₀ means that the light focusing performance is high and the focusing can be performed up to the level corresponding to the wavelength of the laser beam.

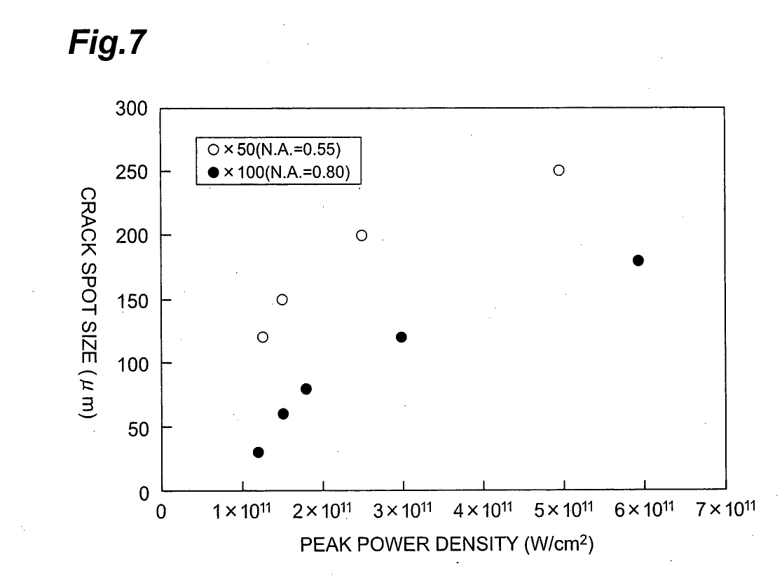

FIG. 7 is a graph showing the result of the above-described experiment. The abscissa axis represents the density of peak power, and the electric field intensity is represented by the peak power density because the laser beam is a pulse laser beam. The ordinate axis represents the size of a crack portion (crack spot) formed inside a processing target object by one-pulse laser beam. The crack spots gather together and become a crack area. The size of the crack spot is the size of a portion having the maximum length in the crack spot shape. Data indicated by black dots in the graph are obtained when the magnification of the condenser lens (C) is set to 100 times and the numerical aperture (NA) is set to 0.80. The data indicated by white dots in the graph are obtained when the magnification of the condenser lens (C) is set to 50 times and the numerical aperture (NA) is set to 0.55. Under the peak power density of about 10¹¹(W/cm²) or more, crack spots occur in the substrate, and the size of the crack spot increases as the peak power density is increased.

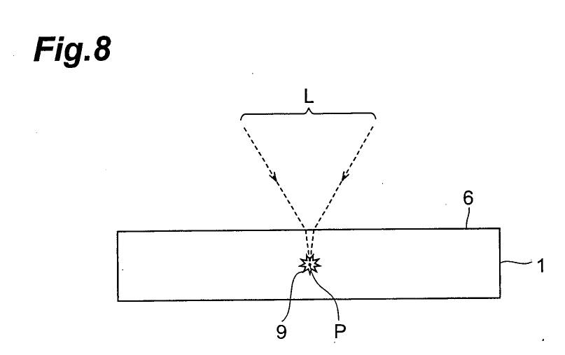

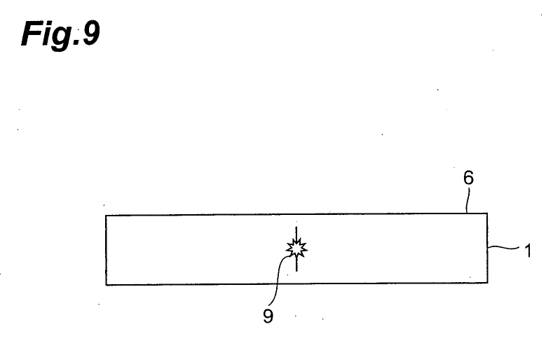

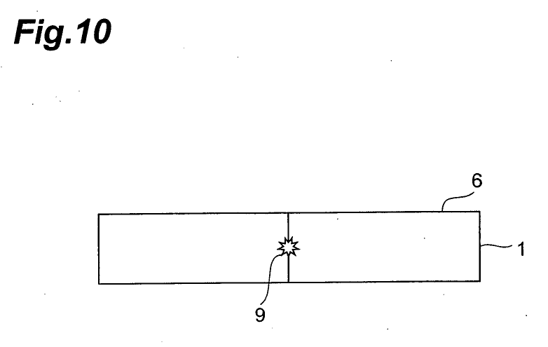

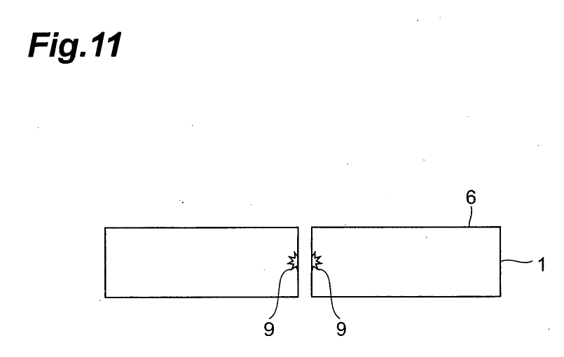

Next, the cutting mechanism of the processing target object through the formation of the crack area in the laser processing method described above will be described with reference to FIG. 8 to FIG. 11. As shown in FIG. 8, under the condition that multiphoton absorption occurs, the condense point P is focused to the inside of the processing target object 1, and the laser beam L is irradiated to the processing target object 1 to form a crack area 9 in the processing target object 1 along the cutting planned line 5. The crack area 9 contains one or a plurality of cracks. The cutting starting point region is formed by the crack area 9. As shown in FIG. 9, a crack is further grown with the crack area 9 as a starting point (that is, with the cutting starting point region as a starting point), and the crack reaches both the surfaces of the processing target object 1 as shown in FIG. 10, and the processing target object 1 is broken as shown in FIG. 11, so that the processing target object 1 is cut. The crack extending to both the surfaces of the processing target object may be grown naturally or by applying force to the processing target object.

(2) When the modified region is molten processed region

For example, the condense point is focused to the inside of the processing target object formed of GaAs, Si or the like, and the laser beam is irradiated under the condition that the electrical field intensity at the condense point is equal to 1×10⁸(W/cm²) or more and the pulse width is set to 1 μs or less. Accordingly, the inside of the processing target object is locally heated by multiphoton absorption. This heating forms a molten processed region inside the processing target object. The molten processed region is an area which is temporarily melted and then re-solidified, an area under a molten state or an area whose state is shifted from the molten state to a re-solidified state, or it may be a phase-changed area or an area whose crystal structure is varied. Furthermore, the molten processed region may be an area in which some structure of the monocrystal structure, the amorphous structure and the polycrystalline structure is varied to another structure. That is, it is an area whose crystal structure is varied from the monocrystal structure to the amorphous structure, an area whose crystal structure is varied from the monocrystal structure to the amorphous structure, an area whose crystal structure is varied from the monocrystal structure to a structure containing the amorphous structure and the polycrystalline structure. When the substrate has an Si monocrystal structure, the molten processed region is has an amorphous Si structure, for example. The upper limit value of the electric field intensity is equal to 1×10¹²(W/cm²), for example. The pulse width is preferably set to ins to 200 ns, for example. Furthermore, the molten processed region may be formed of diamond, sapphire or the like in place of Si.

The inventor has experimentally confirmed that the molten processed region is formed inside a silicon wafer. The experiment condition is as follows.

(A) Substrate: silicon wafer (350 μm in thickness, 4 inches in outer diameter)

(B) Laser

light source: semiconductor laser pumping Nd:YAG laser
wavelength: 1064 nm
cross-sectional area of laser beam spot: 3.14×10⁻⁸ cm²
oscillating mode: Q switch pulse
repetitive frequency: 100 kHz
pulse width: 30 ns
output: 20 μJ/pulse
laser beam quality: TEM₀₀
polarization characteristic: linear polarization
   (C) Condenser lens
magnification: 50 times
N.A.: 0.55
transmittance to laser beam wavelength: 60%
   (D) Moving speed of mount table on which substrate is mounted: 100 mm/second

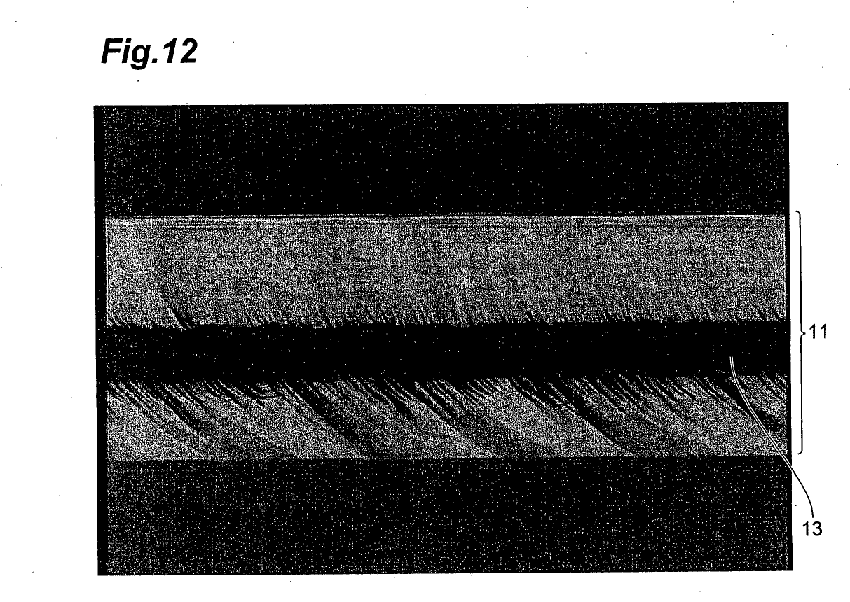

FIG. 12 is a photograph of the cross-section of a part of a silicon wafer cut by the laser processing under the above condition. A molten processed region 13 is formed in the silicon wafer 11. The size in the thickness direction of the molten processed region 13 formed under the condition is equal to about 100 μm.

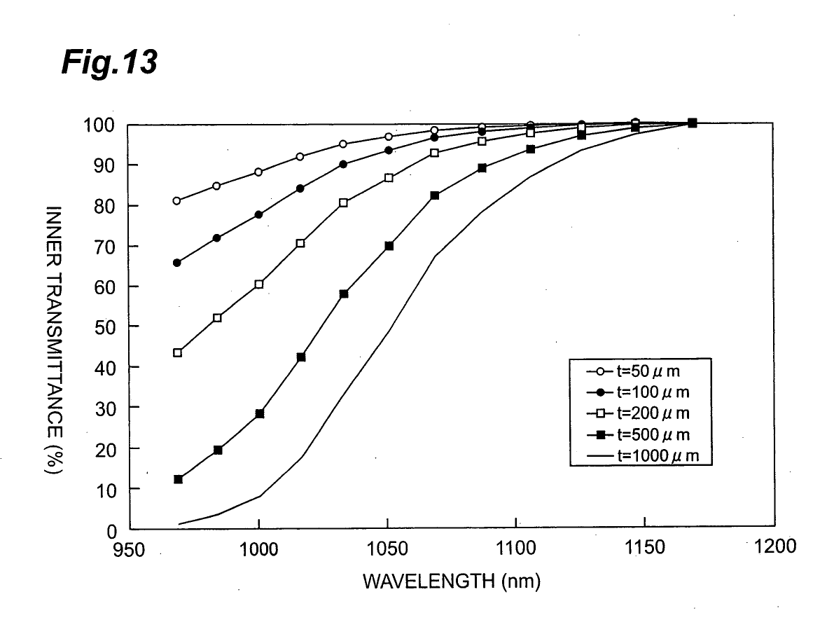

The formation of the molten processed region 13 through the multiphoton absorption will be described. FIG. 13 is a graph showing the relationship between the wavelength of the laser beam and the transmittance of the inside of the Si substrate. In this case, the reflection components of the surface side and the back surface side of the Si substrate are removed, and the transmittance of only the inside is shown. The above relationship is shown for the Si substrate thickness of 50 μm, 100 μm, 200 μm, 500 μm, and 1000 μm.

For example, when the thickness of the Si substrate is 500 μm or less at the wavelength of 1064 nm of Nd:YAG laser, it is apparent that the laser beam of 80% or more is transmitted through the inside of the Si substrate. The thickness of the silicon wafer 11 shown in FIG. 12 is equal to 350 μm, and thus if the molten processed region 13 based on the multiphoton absorption is formed in the vicinity of the center of the silicon wafer, it is formed at the portion of 175 μm from the laser beam incident face. In this case, the transmittance is equal to 90% or more by referring to the silicon wafer of 200 μm in thickness. Therefore, the laser beam is slightly absorbed in the silicon wafer 11, and most of the laser beam is transmitted through the silicon wafer 11. This means that the molten processed region 13 is formed inside the silicon wafer 11 not by the absorption of the laser beam in the silicon wafer 11 (that is, the molten processed region 13 is not formed by normal heating of the laser beam), but the molten processed region 13 is formed by the multiphoton absorption.

In the silicon wafer, crack occurs so as to extend in the cross-sectional direction with the cutting starting point region formed by the molten processed region as a starting point, and the crack reaches both the surface and back surface of the silicon wafer, so that the silicon wafer is cut. The crack extending to both the surfaces of the silicon wafer may be grown naturally or by applying force to the surface of the silicon wafer. When the crack is naturally grown from the cutting starting point region to the surface and back surface of the silicon wafer, there is a case where the crack is grown from the state that the molten processed region forming the cutting starting point region is melted and a case where the crack is grown when the molten processed region is re-solidified from the state that the molten processed region is melted. In both the cases, the molten processed region is formed only inside the silicon wafer, and the molten processed region is formed at only the inside of the silicon wafer on the cut surface after the cutting as shown in FIG. 12. When the cutting starting point region is formed inside the substrate by the molten processed region, at the breaking and cutting time, unnecessary crack out of the cutting starting point region line hardly occurs, and thus the breaking and cutting control can be easily performed.

(3) When the modified region is refractive index varying area

The condense point is focused to the inside of the processing target object of glass or the like, and the laser beam is irradiated under the condition that the electric field intensity at the condense point is equal to 1×10⁸(W/cm²) or more and the pulse width is equal to 1 ns or less. When the pulse width is extremely shortened and multiphoton absorption is induced inside the processing target object, the energy of the multiphoton absorption is not transformed to heat energy, but permanent structural variation such as variation of ionic valence, crystallization, polarization orientation or the like is induced in the processing target object, so that a refractive-index varied area is formed. The upper limit value of the electric field intensity is set to 1×10¹²(W/cm²), for example. The pulse width is preferably set to 1 ns or less, for example, and also more preferably set to 1 ps or less.

The cases (1) to (3) for the modified region formed by the multiphoton absorption have been described. However, if the cutting starting point region is formed in consideration of the crystal structure, cleavage, etc., of the processing target object, the processing target object can be cut with the cutting starting point region as a starting point by smaller force and with higher precision.

That is, when the processing target object is formed of a monocrystal semiconductor having a diamond structure such as Si or the like, it is preferable that the cutting starting point region is formed in a direction along (111)-face (first cleavage face) or (110)-face (second cleavage face). When the processing target object is formed of III-V group compound semiconductor having a lead marcasite type structure such as GaAs or the like, it is preferable that the cutting starting point region is formed in a direction along the (110)-face. Furthermore, when the processing target object has a crystal structure of a hexagonal system such as sapphire or the like, it is preferable that the cutting starting point region is formed in a direction along the (1120)-face (A-face) or (1100)-face (M-face) with the (0001)-face (C-face) as the principal face.

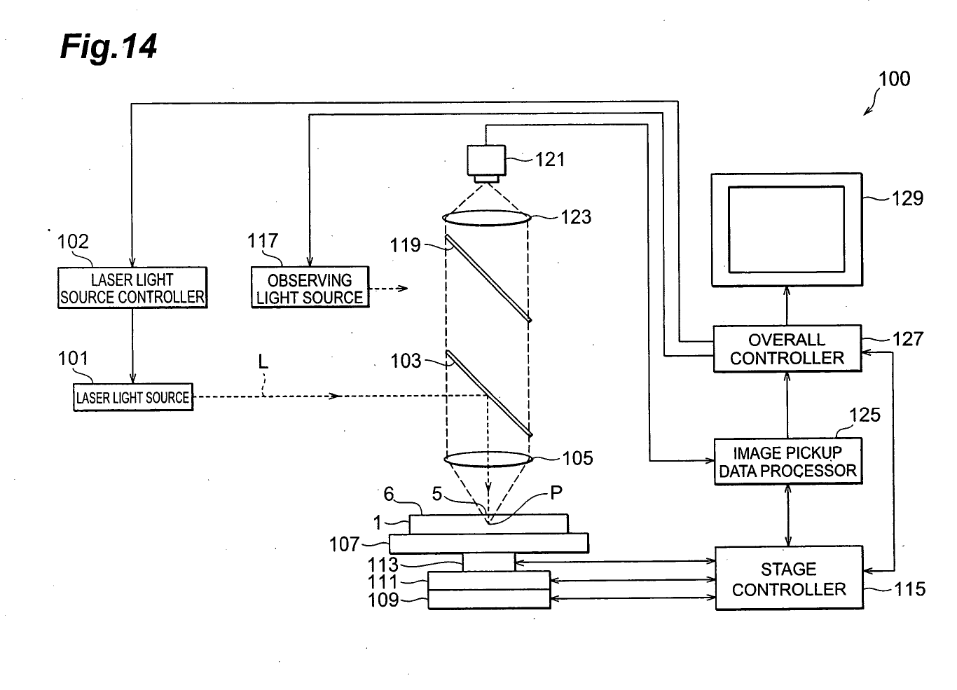

Next, a laser processing device used for the above-described later processing method will be described with reference to FIG. 14. FIG. 14 is a diagram showing the construction of the laser processing device 100.

The laser processing device 100 includes a laser light source 101 for generating a laser beam L, a laser light source controller 102 for controlling the laser light source 101 to adjust the output, the pulse width, etc., of the laser beam L, a dichroic mirror 103 that has a reflection function of the laser beam L and is disposed so as to change the direction of the optical axis of the laser beam L by 90°, a condenser lens 105 for focusing the laser beam L reflected from the dichroic mirror 103, a mount table 107 for mounting the processing target object 1 to which the laser beam L focused by the condenser lens 105 is irradiated, an X-axis stage 109 for moving the mount table 107 in the X-axis direction, a Y-axis stage 111 for moving the mount table 107 in the Y-axis direction perpendicular to the X-axis direction, a Z-axis stage 113 for moving the mount table 107 in the Z-axis direction perpendicular to both the X-axis and Y-axis directions, and a stage controller 115 for controlling the movement of these three stages 109, 111, and 113.

The movement of the condense point P in the X(Y)-axis direction is carried out by moving the processing target object 1 in the X(Y)-axis direction through the X(Y)-axis stage 109(111). The Z-axis direction corresponds to the direction perpendicular to the surface 6 of the processing target object 1, and thus it corresponds to the direction of the focal depth of the laser beam L made incident to the processing target object 1. By moving the Z-axis stage 113 in the Z-axis direction, the condense point P of the laser beam L can be focused to the inside of the processing target object 1. Accordingly, the condense point P can be focused to a desired inner position within a predetermined distance from the surface 6 of the processing target object 1. Furthermore, the laser processing device 100 may comprises an angle adjusting mechanism for adjusting the inclination (tilt) of the processing target object 1 in addition to the above stages.

The laser light source 101 is an Nd:YAG laser for generating a pulse laser beam. In addition to the above laser, Nd:YVO₄ laser, Nd:YLF laser or titan sapphire laser may be used as the laser light source 101. In the embodiment, the pulse laser beam is used for the processing of the processing target object 1, however, a continuous wave laser beam may be used insofar as it can induce multiphoton absorption.

The laser processing device 100 further comprises an observing light source 117 for generating visible light to be irradiated to the processing target object 1 mounted on the mount table 107, dichroic mirror 103 and a visible light beam splitter 119 disposed on the same optical axis as the condenser lens 105. The dichroic mirror 103 is disposed between the beam splitter 119 and the condenser lens 105. The beam splitter 119 has a function of reflecting about half of the visible light and transmitting the residual half of the visible light, and is disposed so as to change the direction of the optical axis of the visible light by 90°. About half of the visible light generated from the observing light source 117 is reflected, and the thus reflected visible light is transmitted through the dichroic mirror 103 and the condenser lens 105 and irradiated to the surface 6 containing the cutting planned line 5 or the like of the processing target object 1. When the processing target object 1 is mounted on the mount table 107 so that the back surface of the processing target object 1 is located at the condenser lens 105 side, “surface” described here corresponds to “back surface.”

The laser processing device 100 further comprises a beam splitter 119, a dichroic mirror 103, and an image pickup device 121 and an imaging lens 123 that are disposed on the same optical axis as the condenser lens 105. For example, a CCD camera is used as the image pickup device 121. The reflection light of visible light irradiated to the surface 6 containing the cutting planned line 5 or the like is transmitted through the condenser lens 105, the dichroic mirror 103 and the beam splitter 119, imaged by the imaging lens 123 and then picked up by the image pickup device 121 to become image pickup data.

The laser processing device 100 further comprises an image pickup data processor 125 to which the image pickup data output from the image pickup device 121 is input, an overall controller 127 for controlling the whole of the laser processing device 100, and a monitor 129. The image pickup data processor 125 calculates focal point data for allocating the focal point of the visible light generated from the observing light source 117 at the surface 6 of the processing target object 1 on the basis of the image pickup data. The stage controller 115 controls the movement of the Z-axis stage on the basis of the focal point data so that the focal point of the visible light is allocated at the surface 6 of the processing target object 1. Accordingly, the image pickup data processor 125 functions as an automatic focus unit. Furthermore, the image pickup data processor 125 operates the image data of an enlarged imaged or the like on the surface 6 on the basis of the image pickup data. The image data concerned is transmitted to the overall controller 127, subjected to various processing in the overall controller 127 and then fed to the monitor 129, whereby the enlarged image or the like is displayed on the monitor 129.

Data from the stage controller 115, the image data or the like from the image pickup data processor 125 are input to the overall controller 127, and the overall controller 127 controls the laser light source controller 102, the observing light source 117 and the stage controller 115 on the basis of these data to thereby control the whole of the laser processing device 100. Accordingly, the overall controller 127 functions as a computer unit.

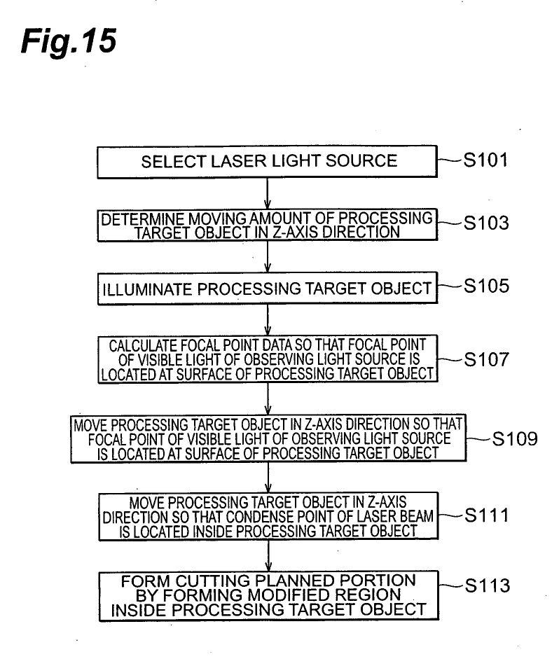

Next, the laser processing method using the laser processing device 100 will be described with reference to FIG. 14 and FIG. 15. FIG. 15 is a flowchart for explaining the laser processing method.

First, the light absorption characteristic of the processing target 1 is measured by a spectrophotometer (not shown), and a laser light source 101 for generating a laser beam L having a wavelength that is transparent to the processing target object 1 or has slight absorption is selected on the basis of the measurement result concerned (S101).

Subsequently, the movement amount of the processing target object 1 in the Z-axis direction is determined in consideration of the thickness and refractive index of the substrate of the processing target object 1 (S103). This is the movement amount in the Z-axis direction of the processing target object 1 with respect to the condense point P of the laser beam L located at the surface 6 of the processing target object 1 in order to focus the condense point P of the laser beam L to a desired position in the processing target object 1. This movement amount is input to the overall controller 127.

The processing target object 1 is placed on the mount table 107 of the laser processing device 100 so that the surface thereof is located at the condenser lens 105 side. The visible light from the observing light source 117 is irradiated to the surface of the processing target object 1 (S105). The image of the surface 6 containing the cutting planned line 5 thus irradiated is picked up by the image pickup device 121. The cutting planned line 5 is a desired virtual line along which the processing target object 1 is cut. The image pickup data picked up by the image pickup device 121 is fed to the image pickup data processor 125. The image pickup data processor 125 operates the focal point data on the basis of the image pickup data concerned so that the focal point of the visible light of the observing light source 117 is allocated at the surface 6 of the processing target object 1 (S107).

This focal point data is fed to the stage controller 115. The stage controller 115 moves the Z-axis stage 113 in the Z-axis direction on the basis of the focal point data (S109). Accordingly, the focal point of the visible light of the observing light source 117 is located at the surface 6 of the processing target object 1. The image pickup data processor 125 operates the enlarged image data of the processing target object 1 containing the cutting planned line 5 on the basis of the image pickup data. The enlarged image data is fed to the monitor 129 via the overall controller 127, whereby the enlarged image around the cutting planned line 5 is displayed on the monitor 129.

The movement amount data determined in step S103 is input to the overall controller 127 in advance, and fed to the stage controller 115. On the basis of the movement amount data, the stage controller 115 moves the processing target object 1 in the Z-axis direction by the Z-axis stage 113 so that the condense point P of the laser beam L is located at the inside of the processing target object 1 (S111).

Subsequently, the laser light source 101 generates the laser beam L, and irradiates the laser beam L to the cutting planned line 5 of the surface 6 of the processing target object 1. Since the condense point P of the laser beam L is located inside the processing target object 1, a modified region is formed only inside the processing target object 1. Then, the X-axis stage 109 and the Y-axis stage 111 are moved along the cutting planned line 5, and a cutting planned portion along the cutting planned line 5 defined by the modified region formed along the cutting planned line 5 is formed inside the processing target object 1 (S113).

As described above, according to the laser processing method, the laser beam L is irradiated from the surface 6 side of the processing target object 1 on the basis of the cutting starting point region 8 along the desired cutting planned line 5 for cutting the processing target object 1, whereby the modified region 7 based on the multiphoton absorption can be formed inside the processing target object 1. The position of the modified region 7 formed inside the processing target object 1 is controlled by adjusting the focusing position of the condense point P of the laser beam L. Accordingly, the processing target object 1 can be broken and cut by relatively small force while the cutting starting point region 8 defined by the modified region 7 formed inside the processing target object 1 is set as a starting point.

Next, embodiments of the semiconductor chip manufacturing method using the above-described laser processing method, and the semiconductor chip and the semiconductor thin film chip that are manufactured by the manufacturing method will be described. In the following embodiments, the substrate on which the semiconductor thin film is formed is set to an Si substrate, and the semiconductor thin film formed on the Si substrate is set to a diamond thin film.

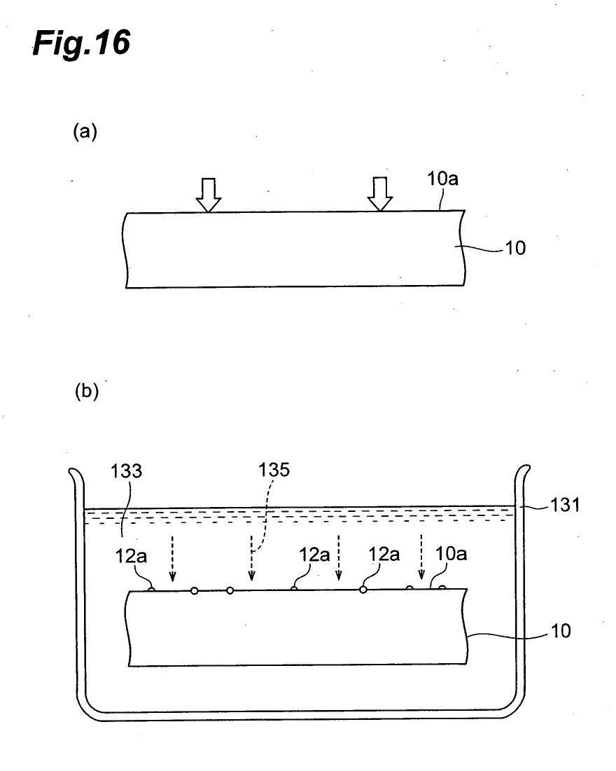

FIGS. 16 to 21 are diagrams for explaining the method of manufacturing the semiconductor chip and the semiconductor thin film chip. First, as shown in the area (a) of FIG. 16, the Si substrate 10 is prepared. Then, the surface 10a of the Si substrate 10 is polished, whereby the surface 10a is finished as a flat and smooth surface.

Subsequently, as shown in the area (b) of FIG. 16, diamond particles 12a serving as seeds to grow the semiconductor thin film are embedded in the surface 10a of the Si substrate. First, the diamond particles of several nm to several tens nm in particle diameter are dispersed into isopropyl alcohol 133 in a water tank. Then, ultrasonic wave 135 is applied to the surface 10a of the Si substrate 10 and the peripheral portion thereof in the water tank 131, whereby the diamond particles 12a in the isopropyl alcohol 133 are embedded in the surface 10a. For example, the amounts of isopropyl alcohol 133 and diamond particles are set to 1 liter and 5 carat, respectively.

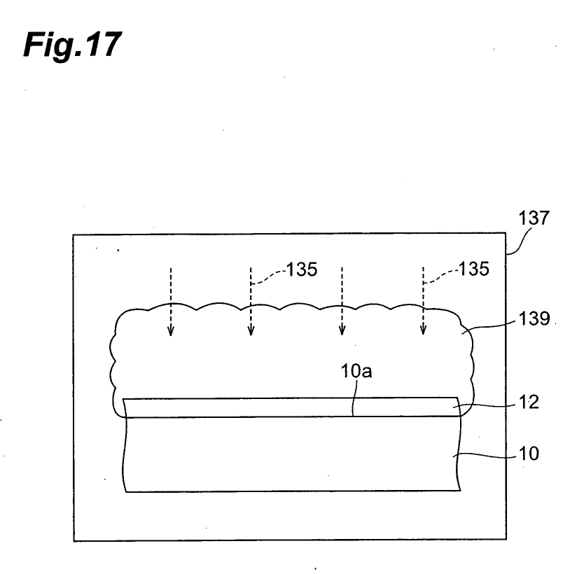

Subsequently, a diamond thin film 12 is formed on the surface 10a of the Si substrate 10 by a microwave plasma CVD method. First, as shown in FIG. 17, the Si substrate 10 is set in the chamber 137 of a plasma CVD device. At this time, the Si substrate is set so that the surface 10a (that is, the surface embedded with the diamond particles 12a) is placed face up. The inner pressure of the chamber 137 is reduced, and microwaves (for example, 2.45 GHz in frequency) are irradiated to the vicinity of the surface 10a of the Si substrate 10 to generate plasma 139. At this time, reaction gas 135 of hydrogen, methane oxygen, etc., is introduced into the chamber 137, so that the diamond thin film 12 is grown on the surface 10a of the Si substrate 10. When the diamond thin film 12 is set to a p-type semiconductor, hydrogen-diluted diborane is introduced in addition to each gas as the reaction gas 135. After the diamond thin film 12 is grown to have a predetermined thickness as described above, the inner pressure of the chamber 137 is returned to the atmospheric pressure and the Si substrate 10 is taken out.

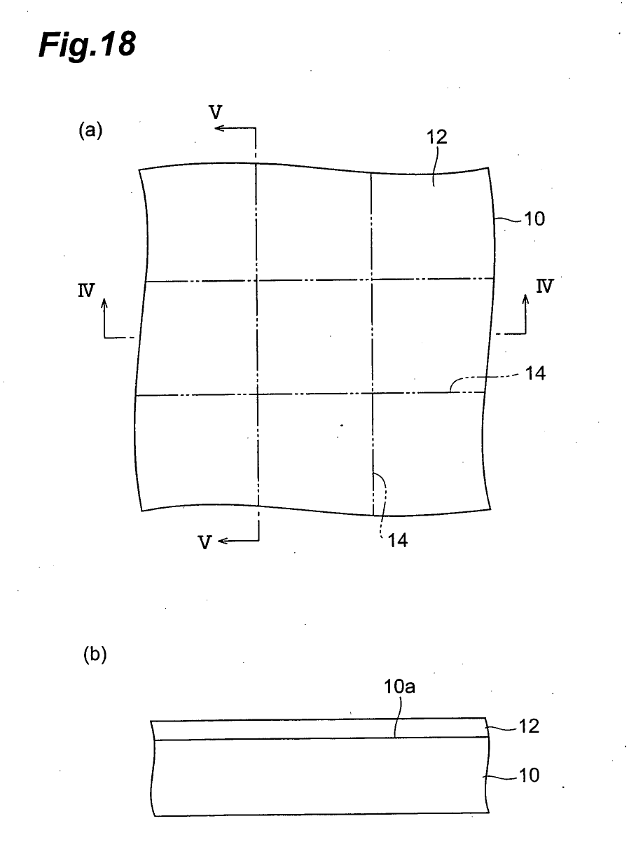

The area (a) of FIG. 18 is a plan view showing the Si substrate 10 and the diamond thin film 12 formed according to the above steps. The area (b) of FIG. 18 is a cross-sectional view showing the Si substrate 10 and the diamond thin film 12 shown in the area (a) of FIG. 18 which is taken along IV-IV line. Referring to the areas (a) and (b) of FIG. 18, the diamond thin film 12 is formed on the surface 10a of the Si substrate 10. In the subsequent step, the Si substrate 10 and the diamond thin film 12 are cut into chips along the cutting planned line 14. In the embodiment, the cutting planned line 14 is assumed to be in a grid form on the surface of the diamond thin film 12.

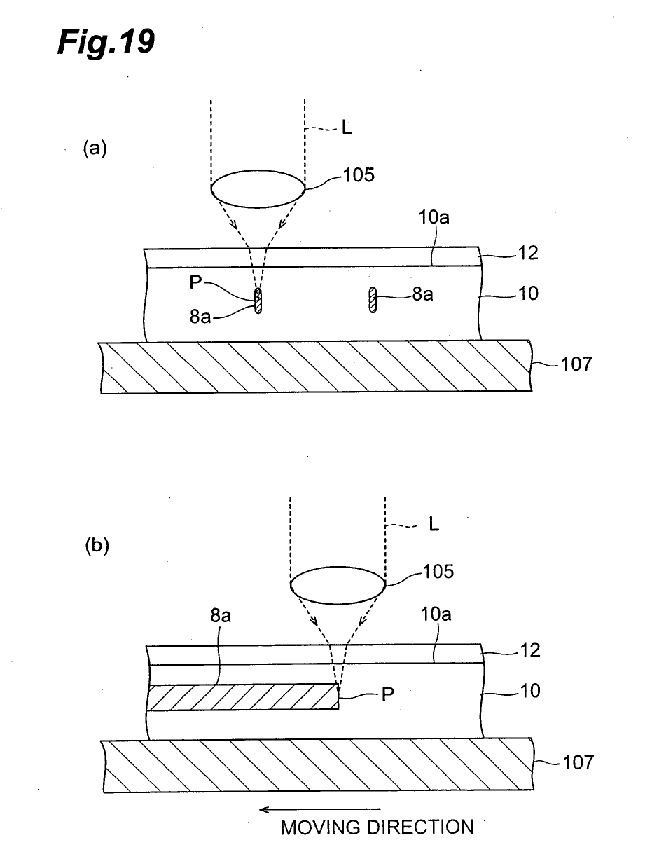

Subsequently, as shown in the areas (a) and (b) of FIG. 19, the cutting starting point region 8a is formed inside the Si substrate 10. First, the Si substrate 10 is set on the mount table 107 of the laser processing device 100 (see FIG. 14). At this time, the Si substrate 10 is fixed to the mount table 107 by adsorption. Furthermore, the surface 10a of the Si substrate 10 and the condenser lens 105 are facing to each other so that the laser beam L is irradiated from the polished surface 10a of the Si substrate 10 into the Si substrate 10. The tilt of the Si substrate 10 is adjusted to the horizontal position, and then the laser beam L whose condense point P is focused to the inside of the Si substrate 10 is irradiated to the Si substrate 10. The laser beam L is set to pulse waves. At this time, the mount table 107 is moved by the X-axis stage 109 (or the Y-axis stage 111) while the laser beam L whose condense point P is focused to the inside of the Si substrate 10 is irradiated, whereby the condense point P in the Si substrate 10 is moved (scanned) along the cutting planned line 14. Accordingly, the modified region is formed along the cutting planned line 14 at the condense point P. The cutting starting point region 8a is an area defined by the modified region thus formed. When the cutting starting point region 8a is formed inside the Si substrate 10, the laser beam L may be scanned only once along the cutting planned line 14, or the laser beam L may be scanned a plurality of times along the same cutting planned line 14.

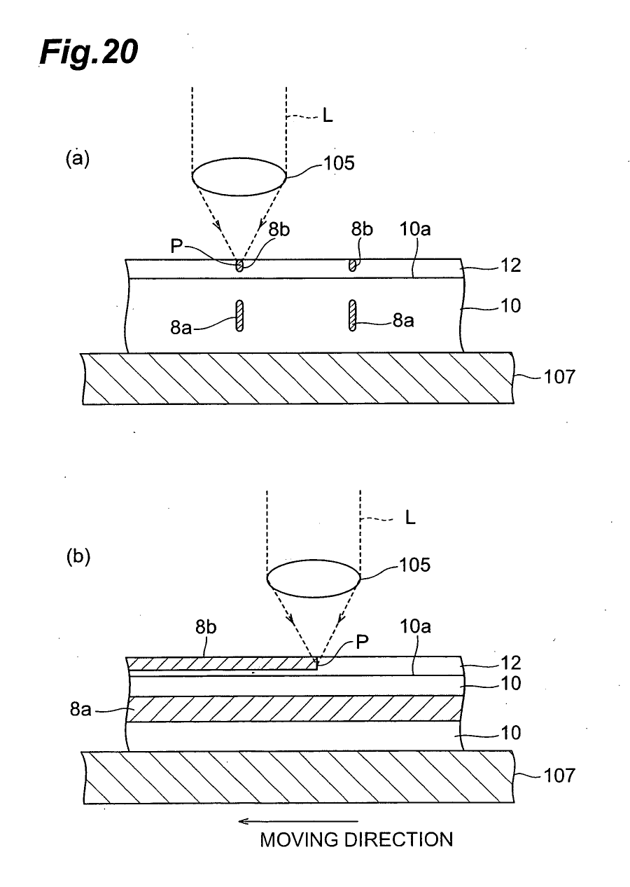

Subsequently, as shown in the areas (a) and (b) of FIG. 20, the cutting starting point region 8b is also formed in the diamond thin film 12. That is, subsequently to the previous step, the laser beam L whose condense point P is focused to the inside of the diamond thin film 12 is irradiated to the diamond thin film 12 under the state that the Si substrate 10 is set on the mount table of the laser processing device 100. The laser beam L of this case is also set to pulse waves. The mount table 107 is moved by the X-axis stage 109 (or the Y-axis stage 111) while the laser beam L whose condense point P is focused to the inside of the diamond thin film 12 is irradiated, whereby the condense point P in the diamond thin film 12 is moved (scanned) along the cutting planned line 14. Accordingly, the modified region is formed along the cutting planned line 14 at the condense point P. The cutting starting point region 8b is an area defined by the modified region formed in the diamond thin film 12. The cutting starting point region 8b is formed so as to extend from the vicinity of the center in the thickness direction of the diamond thin film 12 to the surface of the diamond thin film 12. Furthermore, in the manufacturing method of the semiconductor chip and the semiconductor thin film chip, the step of forming the cutting starting point region 8b may be omitted.

When the cutting starting point regions 8a and 8b are formed, the laser beam L may be made incident from the back surface side of the Si substrate 10. In this case, it is preferable that the back surface of the Si substrate is polished. Alternatively, when the cutting starting point region 8a is formed, the laser beam L may be made incident from the back surface side of the Si substrate 10, and also when the cutting starting point region 8b is formed, the laser beam L may be made incident from the surface 10a side of the Si substrate 10. In this case, it is preferable that at least one of the surface 10a and the back surface of the Si substrate 10 is polished.

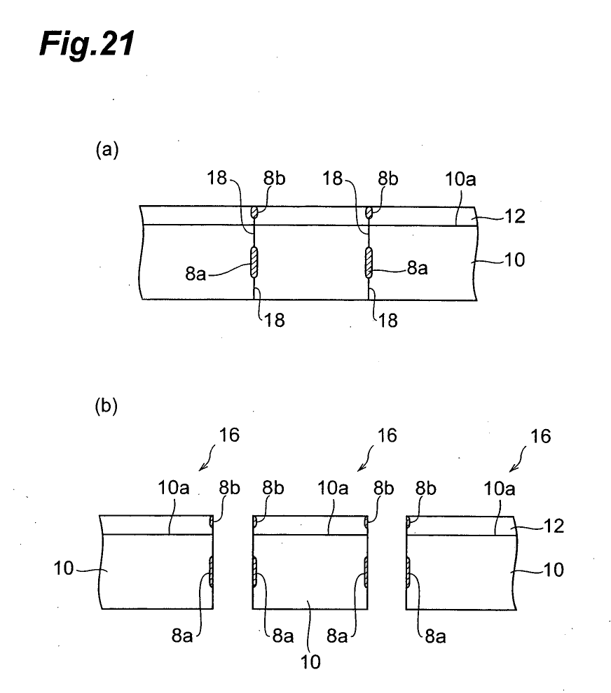

Subsequently, as shown in the area (a) of FIG. 21, crack 18 occurs in the thickness direction of the Si substrate 10 and the diamond thin film 12 with the cutting starting point regions 8a and 8b as a starting point (when the formation of the cutting starting point region 8b is omitted, the cutting starting point region 8a is set as a starting point). As a method of generating the crack 18, the crack 18 may occur by generating a stress in the Si substrate 10 with heat or external force, or the crack 18 may be generated naturally by setting the width of the cutting starting point regions 8a and 8b in the thickness direction of the Si substrate 10 and the diamond thin film 12 to a relatively large value.

Subsequently, as shown in the area (b) of FIG. 21, the Si substrate 10 and the diamond thin film 12 are cut and separated along the cutting starting point regions 8a and 8b (that is, along the cutting planned line 14). As described above, the semiconductor chip 16 containing the semiconductor thin film chip having the diamond thin film 12 formed on the Si substrate 10 is completed.

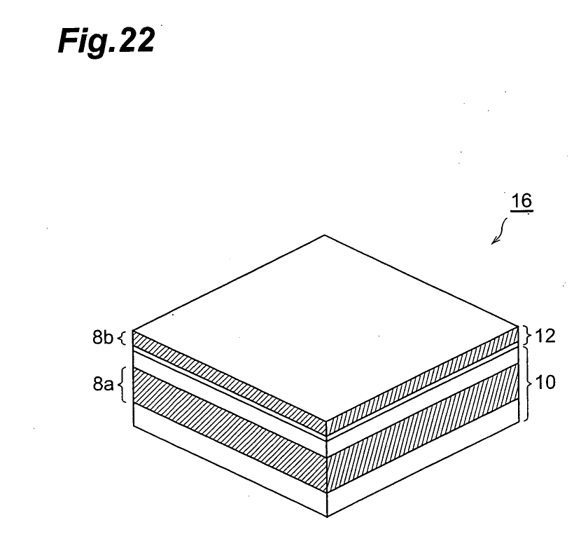

FIG. 22 is a perspective view showing the semiconductor chip 16 (containing the diamond thin film chip corresponding to the semiconductor thin film chip) manufactured by the manufacturing method. In the above-described manufacturing method, the cutting planned line 14 is set in the grid form, and thus the planar shape of the semiconductor chip 16 is rectangular. The semiconductor chip 16 comprises the Si substrate 10 and the diamond thin film (semiconductor thin film chip) formed on the Si substrate 10. The semiconductor chip 16 is cut according to the laser processing method, and thus the cutting starting point regions 8a and 8b including the modified region are exposed to the side surface of the Si substrate 10 and the side surface of the diamond thin film 12.

In accordance with the semiconductor chip manufacturing method, the semiconductor chip and the semiconductor thin film chip, the laser beam L is irradiated to cut the Si substrate 10 and the diamond thin film 12, and thus it is possible to cut the Si substrate 10 and the diamond thin film 12 in a shorter time as compared with the method of forming the groove by using the diamond blade. Furthermore, the Si substrate 10 and the diamond thin film 12 can be broken and cut along the cutting starting point regions 8a and 8b by relatively small force. Therefore, generation of powder dust can be suppressed to a remarkably small level, and no washing step is required. Furthermore, since the Si substrate 10 and the diamond thin film 12 can be broken and cut along the cutting start areas 8a and 8b by relatively small force, the cut surface can be more smoothly formed as compared with the method using the blade dicing as disclosed in the Patent Document 1.

In the method of manufacturing the semiconductor chip, in the step of forming the cutting starting point regions 8a and 8b, it is preferable to form the cutting starting point region 8b in the diamond thin film 12 after the cutting starting point region 8a is formed inside the Si substrate 10. In this case, the cut surface can be more smoothly formed.

According to the semiconductor chip manufacturing method, the diamond thin film 12 is grown on the surface 10a while the surface 10a is made flat and smooth by polishing the surface 10a of the Si substrate 10 before the step of forming the cutting starting point regions 8a and 8b. When the cutting starting point region 8a is formed, the laser beam L is irradiated from the surface 10a side of the Si substrate 10. Accordingly, the scattering of the laser beam L at the surface 10a of the Si substrate 10 can be suppressed, and thus the modified region (molten processed region) can be suitably formed in the Si substrate 10.

In the semiconductor chip manufacturing method, the semiconductor chip and the semiconductor thin film chip, the diamond thin film 12 formed of diamond is grown on the Si substrate 10. However, another material may be mixed in the material of the diamond thin film 12 insofar as the materials contain diamond as a main component. Furthermore, in place of the Si substrate 10, a substrate formed of sapphire, MgF₂, UV glass, synthetic quartz or the like may be used as the substrate on which the diamond thin film 12 is formed.

(Modification)

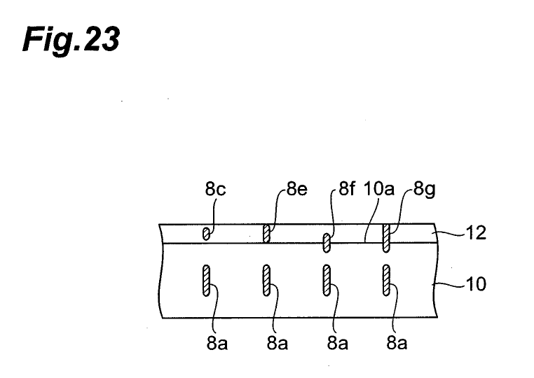

FIG. 23 is a cross-sectional view showing a modification of the semiconductor chip manufacturing method, the semiconductor chip and the semiconductor thin film chip described above. FIG. 23 shows cutting starting point regions 8c to 8g corresponding to the modification on the cutting starting point region 8b (see FIG. 20) formed inside the diamond thin film 12. The cutting starting point region 8c is formed in the vicinity of the center portion in the thickness direction of the diamond thin film 12, and however, it does not extend to the surface of the diamond thin film 12 and the boundary face between the diamond thin film 12 and the Si substrate 10. The cutting starting point region 8d extends from the vicinity of the center portion in the thickness direction of the diamond thin film 12 to the boundary face between the diamond thin film 12 and the Si substrate 10. The cutting starting point region 8e extends to the surface of the diamond thin film 12, and also extends to the boundary face between the diamond thin film 12 and the Si substrate 10. The cutting starting point region 8f is formed so as to extend from the vicinity of the center portion in the thickness direction of the diamond thin film 12 into the Si substrate 10. The cutting starting point region 8g is formed so as to extend from the surface of the diamond thin film 12 into the Si substrate 10. Even when the cutting starting point region is formed like the cutting starting point regions 8c to 8g in this modification, the Si substrate 10 and the diamond thin film 12 can be suitably formed.

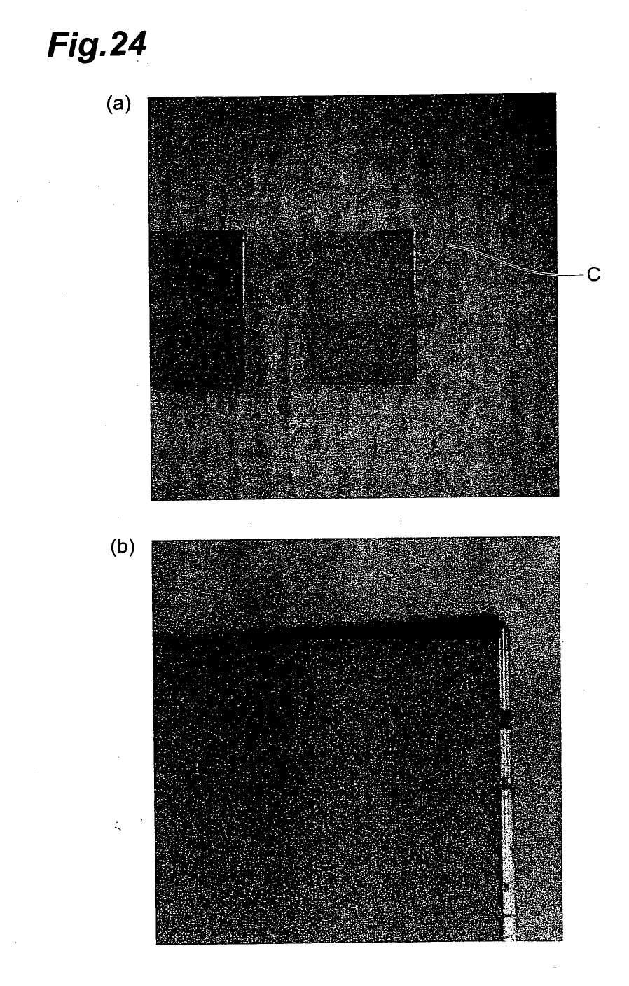

The area (a) of FIG. 24 shows a photograph of a first sample of the semiconductor chip and the semiconductor thin film chip obtained by the above-described manufacturing method. This photograph is obtained by picking up the image of the semiconductor chip 16 from the diamond thin film 12 side. Furthermore, the area (b) of FIG. 24 shows an enlarged photograph of the C portion in the area (a) of FIG. 24. With respect to the first sample, the pulse width of the laser beam L is set to 50 nsec in the laser processing method. By making the laser beam L incident from the surface 10a side of the Si substrate, the cutting starting point regions 8a and 8b are formed inside the Si substrate 10 and the diamond thin film 12. As a result, as shown in the areas (a) and (b) of FIG. 24, the cut surface of the Si substrate 10 and the cut surface of the diamond thin film 12 are aligned with each other, and the cut surfaces can be smoothly formed without exfoliation of the diamond thin film 12 from the Si substrate 10. The intensity of the laser beam L, the repetitive frequency and the stage movement speed are not limited to the numerical values of the first sample, and they may be determined in consideration of the type, the thickness, etc., of the substrate and the semiconductor thin film.

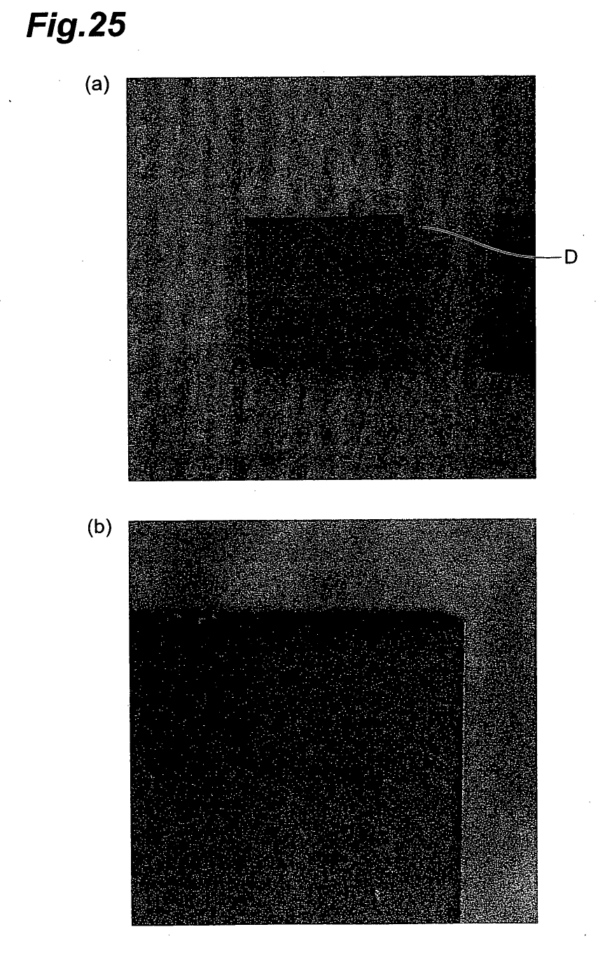

The area (a) of FIG. 25 shows a photograph of a second sample of the semiconductor chip and the semiconductor thin film chip obtained by the above-described manufacturing method. This photograph is obtained by picking up the image of the semiconductor chip 16 from the diamond thin film 12 side as in the case of the area (a) shown in FIG. 24. Furthermore, the area (b) of FIG. 25 shows an enlarged photograph of a D portion in the area (a) of FIG. 25. In the second sample, the laser beam L is scanned at a plurality of times when the cutting starting point region 8a is formed in the Si substrate 10, and the formation of the cutting starting point region 8b in the diamond thin film 12 is omitted. As a result, as shown in the areas (a) and (b) of FIG. 25, although there exists a slight portion at which the cut surface of the Si substrate 10 and the cut surface of the diamond thin film 12 are not aligned with each other, and also there exists a slight portion at which the diamond thin film 12 is exfoliated from the Si substrate 10, the cut surfaces can be nearly smoothly formed. However, comparing the first sample and the second sample, it is found that the diamond thin film 12 can be more suitably formed by forming the cutting starting point region 8b in the diamond thin film 12.

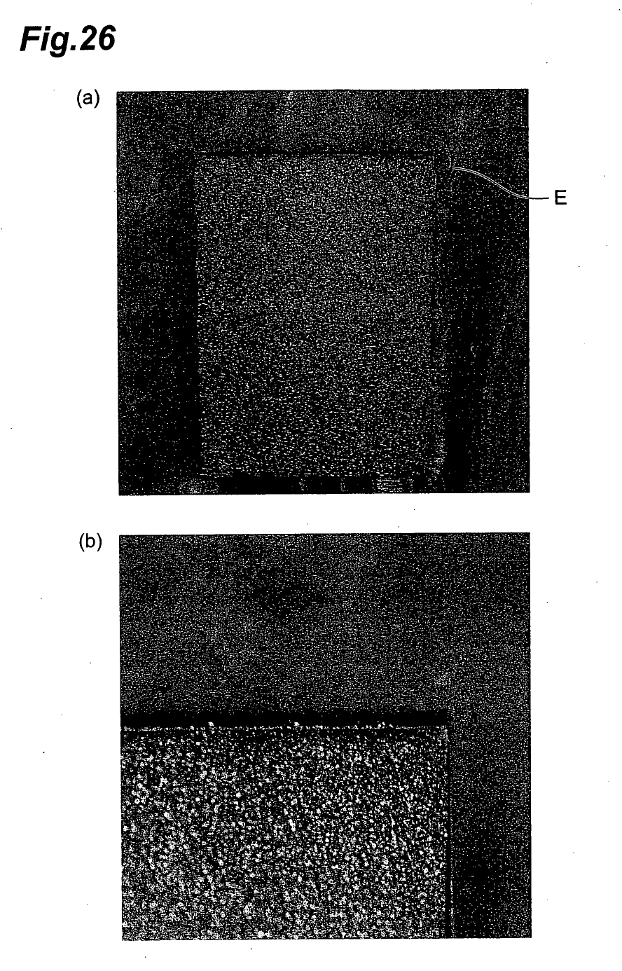

The area (a) of FIG. 26 shows a photograph of a third sample of the semiconductor chip and the semiconductor thin film chip obtained by the above-described manufacturing method. This photograph is obtained by picking up the image of the semiconductor chip 16 from the diamond thin film 12 side as in the case of the area (a) shown in FIG. 24. The area (b) of shows an enlarged photograph of an E portion in the area (a) of FIG. 26. In this third sample, the back surface of the Si substrate 10 is polished to be a flat and smooth surface, and the laser beam L is made incident from the back surface side of the Si substrate 10 to form the cutting starting point region 8a in the Si substrate 10. Furthermore, the laser beam L is made incident from the surface side of the diamond thin film 12 to form the cutting starting point region 8b in the diamond thin film 12. As a result, as shown in the areas (a) and (b) of FIG. 26, the cut surface of the Si substrate 10 and the cut surface of the diamond thin film 12 are aligned with each other, and the cut surfaces can be smoothly formed without exfoliation of the diamond thin film 12 from the Si substrate 10. However, in this sample, since the laser beam L is irradiated from both the front surface and back surface of the Si substrate 10, the working time is longer as compared with the case where the laser beam L is irradiated from any one of the front surface and the back surface. Accordingly, it is preferable that the laser beam L is irradiated from any one of the front surface and the back surface.

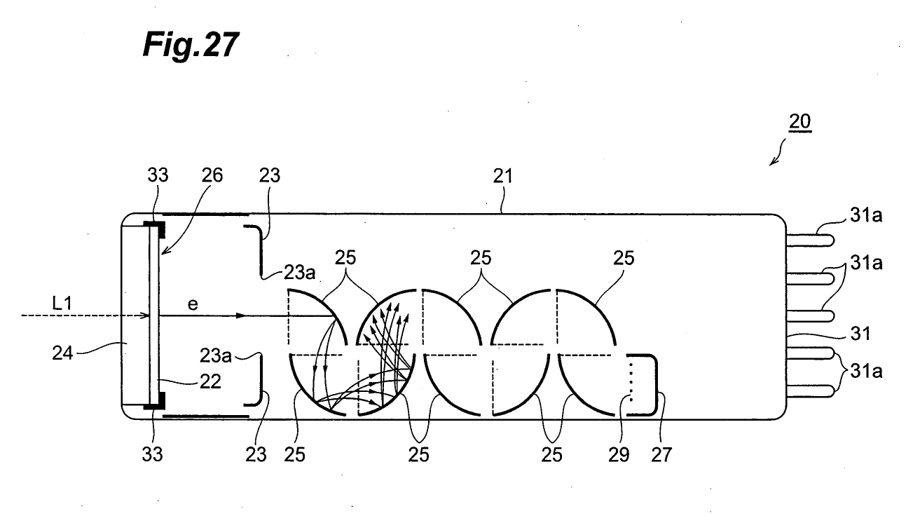

FIG. 27 is a diagram showing the cross-sectional structure of a photomultiplier tube as a first embodiment of an electron tube according to the present invention. Referring to FIG. 27, the photomultiplier tube 20 comprises a semiconductor chip 26. The semiconductor chip 26 has a substrate 24 serving as an incident window to which light L1 is made incident, and a diamond thin film 22 (semiconductor thin film chip) serving as a photoelectric surface formed on the substrate 24. The semiconductor chip 26 is formed in the same manner as the above-described semiconductor chip 16 except that the material of the substrate 24 is different. In the first embodiment, the substrate 24 of the semiconductor chip 26 is formed of MgF₂, for example. That is, diamond as a photoelectric surface has sensitivity to light whose wavelength is shorter than approximately 200 nm, and thus the substrate 24 is formed of MgF₂ through which ultraviolet light of 120 nm or less in wavelength is transmitted, whereby the substrate 24 suitably functions as the incident window. In addition to MgF₂, sapphire, UV glass, synthetic quartz or the like may be used as the material through which light having a wavelength shorter than the limit wavelength of 200 nm of diamond. Furthermore, the diamond thin film 22 may contain other materials insofar as it contains diamond as a main component.

The photomultiplier tube 20 further comprises a bulb 21, a converging electrode 23, a plurality of dynodes 25, a final dynode 27, an anode 29 and a stem 31. The bulb 21 is constructed by a cylindrical glass tube, for example, and it serves as a container to tightly seal the inside of the photomultiplier tube 20 under a vacuum state together with the incident window (substrate 24) and the stem 31. The semiconductor chip 26 is secured to a fixing frame 33 of Ni so that the substrate 24 is located at the outside and the diamond thin film 22 is located at the inside at one end of the bulb 21. With this construction, the light L1 made incident to the photomultiplier tube 20 passes through the substrate 24, and then is made incident to the diamond thin film 22. Photoelectrons e corresponding to the light amount of the light L1 are generated in the diamond thin film 22. The stem 31 is formed of glass, and fusion-bonded to the bulb 21 at the other end of the bulb 21. The stem 31 has a plurality of stem pins 31 a for electrically connecting the photomultiplier tube 20 to external wires. The stem pins 31a are electrically connected to the converging electrode 23, the dynode 25, the final dynode and the anode 29.

The converging electrode 23 is provided in the bulb 21 so as to face the diamond thin film 22 at a predetermined interval. An opening 23a is provided at the center portion of the converging electrode 23, and the photoelectrons e generated in the diamond thin film 22 are drawn out and converged by the converging electrode 23, and pass through the opening 23a. The plurality of dynodes 25 serve as an electron multiplying unit for receiving the photoelectrons emitted from the diamond thin film 22 to generate secondary electrons or receive secondary electrons from another dynode 25 to generate a larger number of secondary electrons. Each of the plurality of dynodes 25 is designed to have a curved surface, and the plurality of stages of the dynodes 25 are repetitively arranged so that the secondary electrons emitted from each dynode 25 are received by another dynode 25. Furthermore, the final dynode 27 finally receives the secondary electrons multiplied by the plurality of dynodes 25, further multiplies the secondary electrons and supplies the multiplied secondary electrons to the anode 29. The anode 29 outputs the secondary electrons from the final dynode 27 via the stem pins 31a to the outside of the photomultiplier tube 20.

The method of manufacturing the photomultiplier tube 20 according to the first embodiment is as follows. The semiconductor chip 26 having the diamond thin film 22 and the substrate 24 is formed by using the same method as the semiconductor chip manufacturing method described above. The semiconductor chip 26 is secured to the fixing frame 33 at the inner side of the bulb 21. The converging electrode 23, the metal plate for the dynode 25, the metal plate for the final dynode 27 and the anode 29 are secured at predetermined positions in the bulb. 21, and these parts are electrically connected to the stem pins 31a. The bulb 21 and the stem 31 are fusion-bonded to each other, and the inside of the bulb 21 is evacuated by using a tube provided to the stem 31. Thereafter, the tube provided to the stem 31 is secured to an exhaust table, and burning is carried out. When the burning is completed, alkali metal is fed into the bulb 21, and firmly fixed to the metal plate for the dynode 25 and the metal plate for the final dynode 27, whereby the dynodes 25 and the final dynode 27 are formed. The type of alkali metal may be suitably selected in accordance with the purpose or application of the electron tube. Furthermore, the diamond thin film 22 has negative affinity, and thus functions as a photoelectric surface. However, if necessary, alkali metal may be fed into the bulb 21 again so that a photoelectric surface formed of alkali metal is formed on the surface of the diamond thin film 22. Finally, the tube provided to the bulb 21 is cut out from the exhaust table, and the photomultiplier tube 20 is completed.

The photomultiplier tube 20 according to the first embodiment is formed of diamond or materials containing diamond as a main component and serves as a photoelectric surface for converting incident light L1 to photoelectrons e, and has the diamond thin film 22 manufactured by the same method as the semiconductor chip manufacturing method described above. Furthermore, the photomultiplier tube 20 comprises the bulb 21, the stem 31 and the substrate 24 for tightly sealing the diamond thin film 22 under a vacuum state. Accordingly, there can be provided the electron tube (photomultiplier tube) that has the photoelectric surface having the cut surface formed smoothly and can be manufactured in a short time.

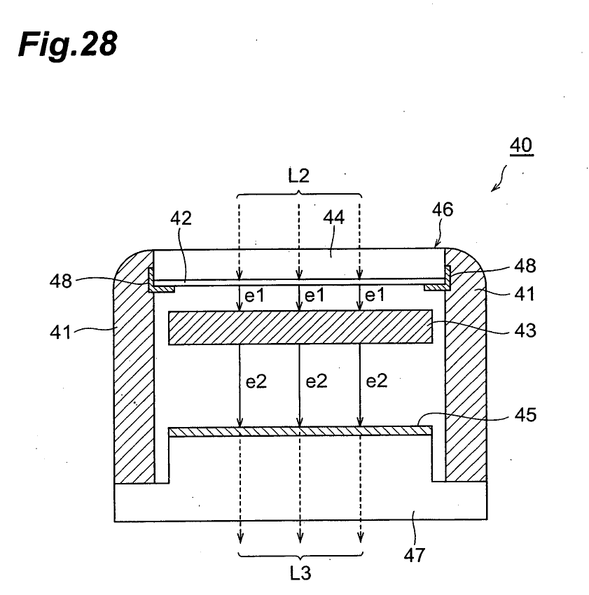

FIG. 28 is a diagram showing the cross-sectional structure of an image tube as a second embodiment of the electron tube of the present invention. Referring to FIG. 28, the image tube 40 according to the second embodiment comprises a semiconductor chip 46. The semiconductor chip 46 has a substrate 44 serving as an incident window to which a light image L2 is made incident, and a diamond thin film 42 (semiconductor thin film chip) serving as a photoelectric surface formed on the substrate 44. The semiconductor chip 46 is formed by the same manufacturing method as the semiconductor chip 16 described above except that the material of the substrate 44 is different. In the second embodiment, the substrate 44 is formed of sapphire, for example. In place of sapphire, MgF₂, UV glass, synthetic quartz or the like may be used as the material of the substrate 44. If the diamond thin film 42 contains diamond as main component, it may contain other materials.

The image tube 40 further comprises a ceramic side tube 41, a microchannel plate (hereinafter referred to as MCP) 43, a fluorescent material 45 and a fiber optic plate (hereinafter referred to as FOP) 47. The ceramic side tube 41 is a container for tightly sealing the inside of the image tube 40 as well as the incident window (substrate 44) and FOP 47 under a vacuum state. The semiconductor chip 46 is secured to the fixing frame 48 so that the substrate 44 is located outside and the diamond thin film 42 is located inside at one end of the ceramic side tube 41. With this construction, the light image L2 made incident to the image tube 40 passes through the substrate 44, and is made incident to the diamond thin film 42, so that photoelectrons e1 corresponding to the light image L2 are generated in the diamond thin film 42. Furthermore, FOP 47 is formed by fusion-bonding a plurality of glass fibers in a bundle, and fixed to the ceramic side tube 41 at the other end of the ceramic side tube 41. The fluorescent material 45 is provided to a surface of FOP 47 which faces the diamond thin film 42, and MCP 43 is disposed between the fluorescent material 45 and the diamond thin film 42. MCP 43 multiplies photoelectrons e1 generated in the diamond thin film 42, and generates secondary electrons e2. When the secondary electrons e2 are made incident to the fluorescent material 45, the fluorescent material 45 emits light in accordance with the secondary electrons e2. That is, the incidence of the secondary electrons e2 into the fluorescent material 45 generates a light image L3 similar to the light image L2 in the fluorescent material 45. The image tube 40 may comprises an electron implanting type CCD or avalanche photodiode in place of the fluorescent material 45.

The method of manufacturing the image tube 40 according to the second embodiment is as follows. The semiconductor chip 46 having the diamond thin film 42 and the substrate 44 is formed by using the same method as the semiconductor chip manufacturing method. The semiconductor chip 46 is secured to the fixing frame 48 in the ceramic side tube 41. MCP 43 is fixed to a predetermined position in the ceramic side tube 41, and electrically connected to the electrode provided to the ceramic side tube 41. FOP 47 provided with the fluorescent material 45 is secured to the end portion of the ceramic side tube 41. The container including the ceramic side tube 41, the substrate 44 and FOP 47 thus formed is placed in the vacuum chamber of 1×10⁻⁷ torr or less, and the inner air is exhausted. Thereafter, if necessary, alkali metal is fed to the surface of the diamond thin film 42, and a photoelectric surface formed of alkali metal is formed. In the vacuum chamber, the boundary between the substrate 44 and the ceramic side tube 41 is tightly sealed by using In, and then the resultant is taken out from the vacuum chamber after being cooled. The image tube 40 is completed as described above.

The image tube 40 according to the second embodiment comprises the diamond thin film 42 (semiconductor thin film chip) that is formed of diamond or materials containing diamond as a main component and that is manufactured as the photoelectric surface for converting the incident light image L2 to the photoelectrons el by the same method as the semiconductor chip manufacturing method. Furthermore, the image tube 40 comprises the ceramic side tube 41, FOP 47 and the substrate 44 for tightly sealing the diamond thin film 42 under a vacuum state. Accordingly, there can be provided the electron tube (image tube) that comprises the photoelectric surface having the smoothly-formed cut face and can shorten the manufacturing time.

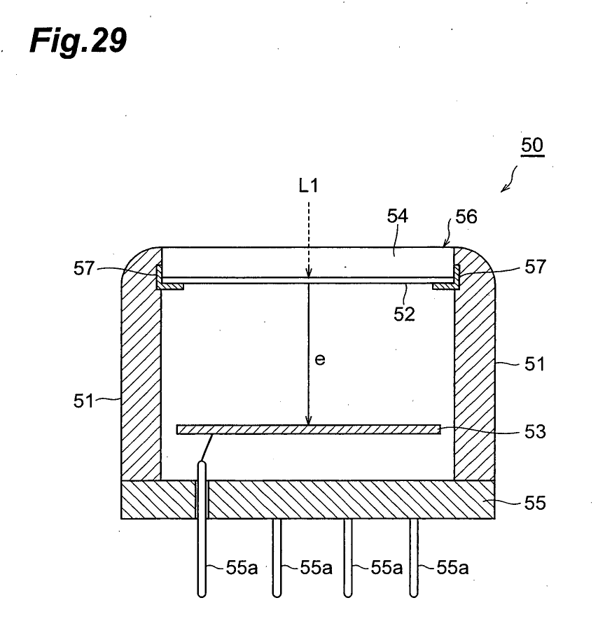

FIG. 29 is a diagram showing the cross-sectional structure of a third embodiment of the electron tube according to the present invention. Referring to FIG. 29, the electron tube 50 according to the third embodiment comprises the semiconductor chip 56. The semiconductor chip 56 has a substrate 54 serving as an incident window to which light L1 is made incident, and a diamond thin film 52 (semiconductor thin film chip) serving as a photoelectric surface formed on the substrate 54. The manufacturing method and the material of the semiconductor chip 56 are the same as the second embodiment.

The electron tube 50 further comprises a package 51, an anode 53 and a stem 55. The package 51 is a container for tightly sealing the inside of the electron tube 50 together with the incident window (substrate 54) and the stem 55. In the third embodiment, the package 51 is formed of metal or glass, for example, and it is designed to have a TO8 type shape. The semiconductor chip 56 is secured to a fixing frame 57 so that the substrate 54 is located outside and the diamond thin film 52 is located inside at one end of the package 51. The stem 55 is fixed to the other end of the package 51. The anode 53 is secured to the inside of the package 51 so as to face the diamond thin film 52, and electrically connected to some stem pins 55a of the plurality of stem pins 55a provided to the stem 55. With this construction, the light L1 made incident to the electron tube 50 passes through the substrate 54, and is made incident to the diamond thin film 52. Then, photoelectrons e corresponding to the light amount of the light L1 are generated in the diamond thin film 52. The photoelectrons e move to the anode 53, and they are taken out via the stem pins 55a to the outside of the electron tube 50.

The manufacturing method of the electron tube 50 according to the third embodiment is as follows. The semiconductor chip 56 having the diamond thin film 52 and the substrate 54 is formed by using the same manufacturing method as the semiconductor chip 16. The semiconductor chip 56 is secured to the fixing frame 57 in the package 51. The anode 53 is fixed to the inside of the package 51, and electrically connected to the stem pins 55a. The stem 55 is fixed to the package 51. The container including the package 51, the substrate 54 and the stem 55 thus formed is placed into the vacuum chamber of 1.0×10⁻⁷ torr or less, and the air therein is exhausted. Thereafter, if necessary, alkali metal is fed to the surface of the diamond thin film 52, and the photoelectric surface of alkali metal is formed. Under the vacuum chamber or in an atmosphere, the boundary between the substrate 54 and the package 51 is tightly sealed by using Al or In, and cooled, thereby completing the electron tube 50.

In accordance with the electron tube 50 of the third embodiment, as in the case of the first and the second embodiment, there can be provided an electron tube that comprises the photoelectric surface having the cut surface formed flatly and smoothly and can shorten the manufacturing time. The electron tube 50 may comprises MCP as electron multiplying means between the diamond thin film 52 and the anode 53 as in the case of the image tube 40 according to the second embodiment.

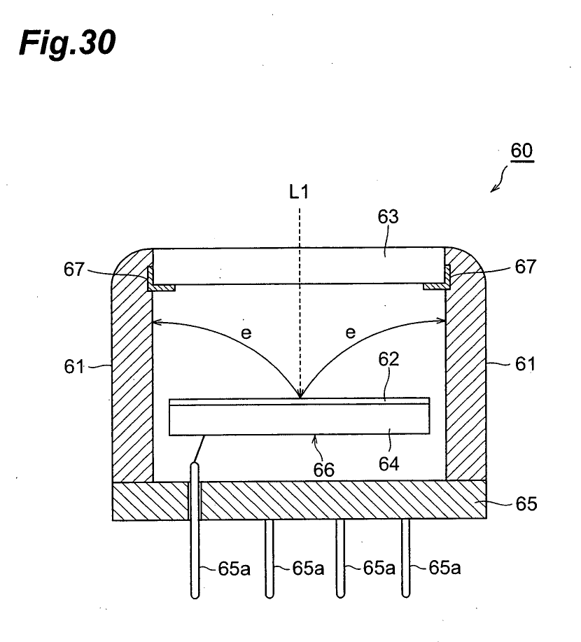

FIG. 30 is a diagram showing the cross-sectional structure of a fourth embodiment of the electron tube according to the present invention. Referring to FIG. 30, an electron tube 60 of the fourth embodiment comprises a semiconductor chip 66. The semiconductor chip 66 has a substrate 64, and a diamond thin film 62 (semiconductor thin film chip) serving as a photoelectric surface formed on the substrate 64. The manufacturing method and materials of the semiconductor chip 66 are the same as the semiconductor chip 16 described above.

The electron tube 60 further comprises a package 61, an incident window 63 and a stem 65. The package 61 is a container for tightly sealing the inside of the electron tube 60 under a vacuum state together with the incident window 63 and the stem 65. In the fourth embodiment, the package 61 is formed of conductive material such as metal, and it is designed in the form of TO8 type. The incident window 63 is formed of, for example, MgF₂, synthetic quartz, UV glass, sapphire or the like, and it is fixed to the fixing frame 67 at one end of the package 61. The stem 65 is formed of electrically conductive material such as metal, and fixed to the other end of the package 61. The chip 66 is fixed to the inside of the package 61 so that the diamond thin film 62 faces the incident window 63, and is electrically connected to some stem pins 65a of the plurality of stem pins 65a provided to the stem 65. The other stem pins 65a of the plurality of stem pins 65a are electrically connected to the package 61 via the stem 65. With this construction, the light L1 made incident to the electron tube 60 passes through the incident window 63, and is made incident to the diamond thin film 62. Accordingly, photoelectrons e corresponding to the light amount of the light L1 are generated in the diamond thin film 62. The photoelectrons e are emitted from the surface to which the light L1 is made incident in the diamond thin film 62, and move to the package 61. The photoelectrons e are taken out from the package 61 via the stem 65 and the stem pins 65a to the outside of the electron tube 60.

The manufacturing method of the electron tube 60 according to the fourth embodiment is as follows. The semiconductor chip 66 having the diamond thin film 62 and the substrate 64 is formed by using the same manufacturing method as the semiconductor chip 16. The semiconductor chip 66 is fixed to the inside of the package 61, and is electrically connected to the stem pins 65a. The incident window 63 is secured to the fixing frame 67 provided to one end of the package 61, and the stem 65 is fixed to the other end of the package 61. The container including the package 61, the incident window 63 and the stem 65 thus formed is placed in the vacuum chamber, and the inner air is exhausted. Thereafter, if necessary, alkali metal is fed to the surface of the diamond thin film 62, and the photoelectric surface formed of alkali metal is formed. Then, in the vacuum chamber or the atmospheric air, the boundary between the incident window 63 and the package 61 is tightly sealed by using Al or In, and cooled, thereby completing the electron tube 60.

In accordance with the electron tube 60 of the fourth embodiment, as in the case of the first to third embodiments, there can be provided the electron tube that comprises the photoelectric surface having the cut surface formed flatly and smoothly and can shorten the manufacturing time.

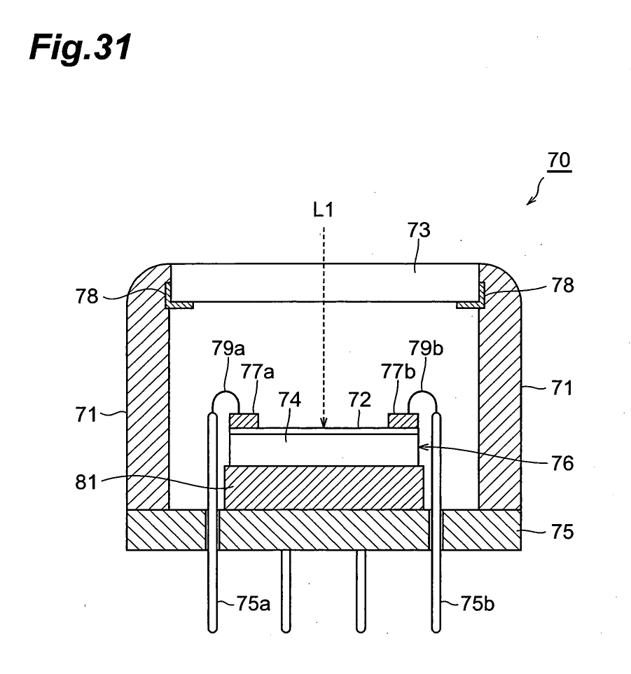

FIG. 31 is a diagram showing the cross-sectional structure of an embodiment of a photo-detecting device according to the present invention. Referring to FIG. 31, the photo-detecting device 70 comprises a semiconductor chip 76. The semiconductor chip 76 has a substrate 74, and a diamond thin film 72 (semiconductor thin film chip) formed on the substrate 74. In the embodiment, the diamond thin film 72 functions as a photo-detecting face for detecting incident light L1.

The manufacturing method and material of the semiconductor chip 76 are the same as the semiconductor chip 16. Furthermore, electrodes 77a and 77b are provided on the diamond thin film 72 of the semiconductor chip 76. The electrodes 77a and 77b are provided on the diamond thin film 72 so as to be spaced from each other.

The photo-detecting device 70 further comprises a package 71, an incident window 73, a stem 75 and a mount table 81. The package 71 is a container for tightly sealing the inside of the photo-detecting device 70 under a vacuum state together with the incident window 73 and the stem 75, and it is designed in a cylindrical form in the embodiment. The incident window 73 is formed of MgF₂, synthetic quartz, UV glass, sapphire or the like, and it is fixed to a fixing frame 78 at one end of the package 71. The stem 75 is fixed to the other end of the package 71. A mount table 81 for mounting the chip 76 thereon is placed on the stem 75. The mount table 81 is formed of metal, for example. The chip 76 is placed on the mount table 81 so that the diamond thin film 72 faces the incident window 73. The electrodes 77a and 77b provided to the chip 76 are electrically connected to stem pins 75a and 75b provided to the stem 75 via wires 79a and 79b, respectively. The stem pins 75a and 75b are connected, for example, to a power supply circuit (not shown), and a predetermined bias voltage is applied between the stem pins 75a and 75b. With this construction, the light L1 made incident to the photo-detecting device 70 passes through the incident window 73 and then is made incident to the diamond thin film 72. The carriers corresponding to the light amount of the light L1 are generated in the diamond thin film 72. The carriers cause the current corresponding to the light amount of the light L1 made incident to the diamond thin film 72 to flow between the electrodes 77a and 77b.

The manufacturing method of the photo-detecting device 70 according to the embodiment is as follows. First, the diamond thin film is formed on a silicon wafer, and then Ni film and Au film are successively deposited on the diamond thin film in this order. At this time, the thickness of the Ni film may be set to 50 nm, and the thickness of the Au film may be set to 300 nm, for example. After a resist is coated on the Au film, a comb-shaped pattern is formed on the resist by using a well-known photolithography technique. Etching is carried out on the Au film and the Ni film via the resist pattern. With respect to the Au film, the silicon wafer is immersed in water solution containing I₂ and KI in the ratio of I₂:KI:H₂O=1:2:10, and then washed with water. Furthermore, with respect to the Ni film, the silicon wafer is immersed in liquid containing the mixture of HNO₃, CH₃COOH and acetone in the ratio of HNO₃:CH₃COOH:acetone (CH₃COCH₃)=1:1:1, and then washed with water. As described above, the Au film and the Ni film are formed in the comb-shaped pattern. The resist is removed by acetone, and the silicon wafer is cleaned and dried by using acetone and methyl alcohol.

As described above, the silicon wafer on which the diamond thin film and the comb-shaped Au film and Ni film are formed is obtained. The silicon wafer thus obtained is cut by a predetermined size according to the laser processing method described above, thereby forming the semiconductor chip 76. At this time, the Au film and the Ni film are cut and become the electrodes 77a and 77b. The semiconductor chip 76 is fixed onto the mount table 81 placed on the stem 75 by adhesive agent such as solder or the like, and the electrodes 77a and 77b are respectively connected to the step pins 75a and 75b by the wires 79a and 79b. The package 71 to which the incident window 73 is secured and the stem 75 are mutually fixed to each other under the vacuum of 1.0×10⁻⁷ torr or less under a nitrogen atmosphere. As described above, the photo-detecting device 70 is completed.

The photo-detecting device 70 of the embodiment comprises the diamond thin film 72 (semiconductor thin film chip) that is formed of diamond or materials containing diamond as a main component and that is manufactured as a photo-detecting face for detecting incident light L1 by the above-described laser processing method. Furthermore, the photo-detecting device 70 comprises the two electrodes 77a and 77b that are provided on the diamond thin film 72 while being spaced from each other. Accordingly, there can be provided the photo-detecting device that comprises the photo-detecting face having the smoothly formed cut surface and can shorten the manufacturing time. The number of electrodes provided on the diamond thin film 72 may be set to two or more.

The semiconductor chip manufacturing method, the semiconductor chip, the semiconductor thin film chip, the electron tube and the photo-detecting device according to the present invention are not limited to the above-described embodiments, and various modifications may be made. For example, in the respective embodiments, the diamond thin film is provided as the semiconductor thin film. However, the material of the semiconductor thin film is not limited to diamond, but other various semiconductors may be used.

### INDUSTRIAL APPLICABILITY

With respect to the semiconductor chip, etc., according to the present invention, the semiconductor thin film can be cut in a relatively short time, and the cut surface can be formed relatively smoothly, and thus the semiconductor chip, etc., can be applied to an electron tube, a photo-detecting device, etc.

1. A semiconductor chip manufacturing method, comprising the steps of:
forming a cutting starting point region along a cutting planned line into a semiconductor member which comprises a substrate and a semiconductor thin film provided on a surface of said substrate, wherein, as a cutting starting point region, a modified region based on multiphoton absorption is formed in said substrate by irradiating said substrate with a laser beam whose condense point is focused to an inside of said substrate, along the cutting planned line; and
cutting said semiconductor thin film by cutting said substrate along the cutting starting point region.

2. A semiconductor chip manufacturing method, comprising the steps of:
forming a cutting starting point region along a cutting planned line in a semiconductor member which comprises a substrate and a semiconductor thin film provided on a surface of said substrate, wherein, as a cutting starting point region, a molten processed region is formed in said substrate by irradiating said substrate with a laser beam whose condense point is focused to an inside of said substrate, along the cutting planned line; and
cutting said semiconductor thin film by cutting said substrate along the cutting starting point region.

3. A semiconductor chip manufacturing method, comprising the steps of:
forming a cutting starting point region along a cutting planned line in a semiconductor member which comprises a substrate and a semiconductor thin film provided on a surface of said substrate, wherein, as cutting starting point regions, modified regions based on multiphoton absorption are formed in said semiconductor thin film and said substrate, by irradiating said substrate with a laser beam whose condense point is focused to an inside of said substrate along the cutting planned line, and by irradiating said semiconductor thin film with a laser beam whose condense point is focused to an inside of said semiconductor thin film along the cutting planned line; and
cutting both said semiconductor thin film and said substrate along the cutting starting point regions.

4. A semiconductor chip manufacturing method, comprising the steps of:
forming a cutting starting point region along a cutting planned line in a semiconductor member which comprises a substrate and a semiconductor thin film provided on a surface of said substrate, wherein, as cutting starting point regions, molten processed regions are formed in said semiconductor thin film and said substrate by irradiating said substrate with a laser beam whose condense point is focused to an inside of said substrate along the cutting planned line, and by irradiating said semiconductor thin film with a laser beam whose condense point is focused to an inside of said semiconductor thin film along the cutting planned line; and
cutting both said semiconductor thin film and said substrate along the cutting starting point regions.

5. A semiconductor chip manufacturing method according to claim 3 or 4, wherein, in the forming of the cutting starting point region, the cutting starting point region is formed in the inside of said semiconductor thin film after the cutting starting point region is formed in the inside of said substrate.

6. A semiconductor chip manufacturing method according to any one of claims 1 to 5, wherein said semiconductor thin film is comprised of one of diamond and materials containing diamond as a main component.

7. A semiconductor chip manufacturing method according to any one of claims 1 to 6, further comprising the step of polishing the surface of said substrate and growing said semiconductor thin film on the surface, prior to the forming of the cutting starting point regions,
wherein, in the forming of the cutting starting point region, the laser beam is irradiated from a substrate surface side.

8. A semiconductor thin film chip that is a part of a semiconductor thin film formed on a surface of a substrate, said semiconductor thin film being cut together with said substrate, along a cutting starting point region defined by a modified region based on multiphoton absorption which is formed by irradiating said substrate with a laser beam whose condense point is focused to an inside of said substrate.

9. A semiconductor thin film chip that is a part of a semiconductor thin film formed on a surface of a substrate, said semiconductor thin film being cut together with said substrate, along a cutting starting point region defined by a molten processed region which is formed by irradiating said substrate with a laser beam whose condense point is focused to an inside of said substrate.

10. A semiconductor thin film chip that is a part of a semiconductor thin film formed on a surface of a substrate, said semiconductor thin film being cut together with said substrate, along a cutting starting point region defined by a modified region based on multiphoton absorption which is formed by irradiating said substrate with a laser beam whose condense point is focused to an inside of said substrate, and by irradiating said semiconductor thin film with a laser beam whose condense point is focused to an inside of said semiconductor thin film.

11. A semiconductor thin film chip that is a part of a semiconductor thin film formed on a surface of a substrate, said semiconductor thin film being cut together with said substrate, along a cutting starting point region defined by a molten processed region which is formed by irradiating said substrate with a laser beam whose condense point is focused to an inside of said substrate, and by irradiating said semiconductor thin film with a laser beam whose condense point is focused to an inside of said semiconductor thin film.

12. A semiconductor thin film chip according to any one of claims 8 to 11, wherein said substrate on which said semiconductor thin film is formed has a flat and smooth surface.

13. A semiconductor thin film chip according to any one of claims 8 to 12, wherein said semiconductor thin film is comprised of one of diamond and materials containing diamond as a main component.

14. A semiconductor chip comprising:
a semiconductor thin film chip according to any one of claims 8 to 13; and
a part of said substrate having said semiconductor thin film chip formed on the surface thereof.

15. An electron tube comprising:
a semiconductor thin film chip according to any one of claims 8 to 13 as a photoelectric surface for converging incident light to photoelectrons; and
a container for tightly sealing said semiconductor thin film chip under a vacuum state.

16. A photo-detecting device comprising:
a semiconductor thin film chip according to any one of claims 8 to 13 as a photo-detecting surface for detecting incident light; and
at least two electrodes provided on said semiconductor thin film chip while being spaced from each other.
